(19) United States
(12) Patent Application Publication
(10) Pub. No.: US 2024/0113214 A1
(43) Pub. Date: Apr. 4, 2024

(54) SEMICONDUCTOR STRUCTURE WITH DIELECTRIC SPACER AND METHOD FOR MANUFACTURING THE SAME

(71) Applicant: Taiwan Semiconductor Manufacturing Company, Ltd., Hsinchu (TW)

(72) Inventors: Che-Lun Chang, Hsinchu (TW); Kuan-Ting Pan, Taipei City (TW); Wei-Yang Lee, Taipei City (TW)

(73) Assignee: Taiwan Semiconductor Manufacturing Company, Ltd., Hsinchu (TW)

(21) Appl. No.: 18/177,909

(22) Filed: Mar. 3, 2023

Related U.S. Application Data
(60) Provisional application No. 63/411,788, filed on Sep. 30, 2022.

(51) Int. Cl. H01L 29/775; H01L 29/06; H01L 29/417; H01L 29/423; H01L 29/66

(52) U.S. Cl. CPC H01L 29/775; H01L 29/0673; H01L 29/41775; H01L 29/42392; H01L 29/66439; H01L 29/66545; H01L 29/66553

(57) ABSTRACT

Semiconductor structures and methods for manufacturing the same are provided. The semiconductor structure includes a first channel member suspended over a substrate and a second channel member suspended over the first channel member and spaced apart from the first channel member along a first direction. The semiconductor structure also includes a gate structure wrapping around the first channel member and the second channel member and a dielectric structure encircled by the first channel member, the second channel member, the gate structure, and the source/drain structure. In addition, the dielectric structure includes a porous material or an air gap. The semiconductor structure also includes a first epitaxial layer attached to the first channel member, and the first epitaxial layer has a first extending portion protruding from a bottom surface of the first channel member along the first direction and extending into the dielectric structure.

### PRIORITY CLAIM AND CROSS-REFERENCE

This application claims priority to U.S. Provisional Application Ser. No. 63/411,788, filed on Sep. 30, 2022, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIG. 1 illustrates a diagrammatic top view of a semiconductor structure in accordance with some embodiments.

FIGS. 2A-1 to 2O-1 illustrate diagrammatic perspective views of intermediate stages of manufacturing the semiconductor structure shown in region R of FIG. 1 in accordance with some embodiments.

FIGS. 2A-2 to 2O-2 illustrate cross-sectional views of the intermediate stages of manufacturing the semiconductor structure shown along line A-A′ of FIG. 1 in accordance with some embodiments.

FIG. 2F-3 illustrates an enlarged cross-sectional view of the semiconductor structure of region R_{2F} shown in FIG. 2F-2 in accordance with some embodiments.

FIG. 2H-3 illustrates an enlarged cross-sectional view of the semiconductor structure of region R_{2H} shown in FIG. 2H-2 in accordance with some embodiments.

FIG. 2I-3 illustrates an enlarged cross-sectional view of the semiconductor structure of region R_{2I} shown in FIG. 2I-2 in accordance with some embodiments.

FIG. 2J-3 illustrates an enlarged cross-sectional view of the semiconductor structure of region R_{2J} shown in FIG. 2J-2 in accordance with some embodiments.

FIG. 2K-3 illustrates an enlarged cross-sectional view of the semiconductor structure of region R_{2K} shown in FIG. 2K-2 in accordance with some embodiments.

FIG. 2O-3 illustrates an enlarged cross-sectional view of the semiconductor structure of region R_{2O} shown in FIG. 2O-2 in accordance with some embodiments.

FIG. 3 illustrates a cross-sectional view of a semiconductor structure in accordance with some embodiments.

FIG. 4 illustrates an enlarged cross-sectional view of a semiconductor structure in accordance with some embodiments.

FIG. 5 illustrates an enlarged cross-sectional view of a semiconductor structure in accordance with some embodiments.

FIGS. 6A to 6D illustrate enlarged cross-sectional views of intermediate stages of manufacturing a semiconductor structure in accordance with some embodiments.

FIGS. 7A and 7B illustrate cross-sectional views of intermediate stages of manufacturing a semiconductor structure in accordance with some embodiments.

FIGS. 8A-1 to 8E-1 illustrate diagrammatic perspective views of intermediate stages of manufacturing a semiconductor structure in accordance with some embodiments.

FIGS. 8A-2 to 8E-2 illustrate cross-sectional views of the intermediate stages of manufacturing the semiconductor structure shown along line A₁-A₁′ in FIG. 8A-1 in accordance with some embodiments.

FIGS. 8A-3 to 8E-3 illustrate enlarged cross-sectional views of the intermediate stages of manufacturing the semiconductor structure of regions R_{8A} to R_{8E} shown in FIGS. 8A-2 to 8E-2 in accordance with some embodiments.

FIG. 9 illustrates an enlarged cross-sectional view of a semiconductor structure in accordance with some embodiments.

FIG. 10 illustrates an enlarged cross-sectional view of a semiconductor structure in accordance with some embodiments.

FIG. 11 illustrates an enlarged cross-sectional view of a semiconductor structure in accordance with some embodiments.

FIG. 12 illustrates a cross-sectional view of a semiconductor structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistors.

Embodiments of semiconductor structures and methods for forming the same are provided. The semiconductor structures may include dielectric structures sandwiched between the channel members. The dielectric structures may include air gap or porous material, which may have a relatively low k value, and the performance of the resulting device may therefore be improved.

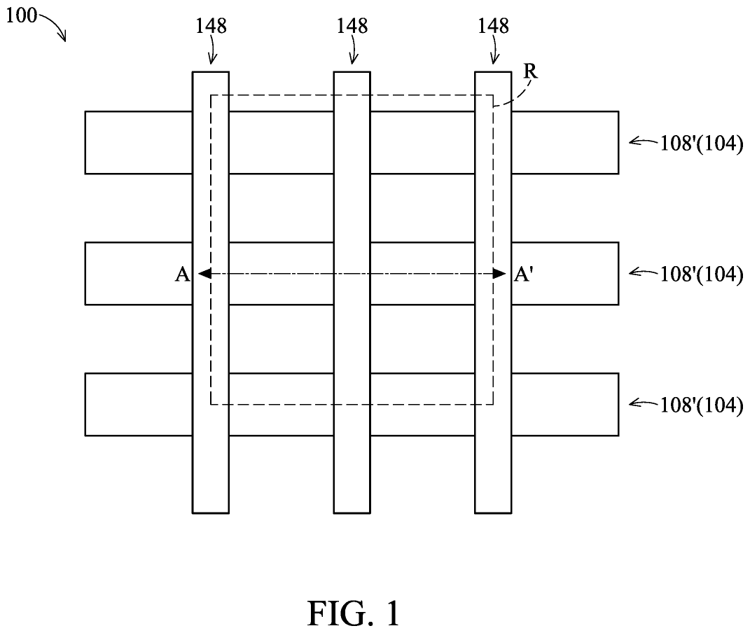

FIG. 1 illustrates a diagrammatic top view of a semiconductor structure 100 in accordance with some embodiments. The semiconductor structure 100 includes channel members 108′ (or fin structures 104) and gate structures 148 in accordance with some embodiments. In some embodiments, the channel members 108′ have longitudinal axis in the X direction, and the gate structures 148 have longitudinal axis in the Y direction. It should be noted that the semiconductor structure 100 shown in FIG. 1 has been simplified for the sake of clarity to better understand the inventive concepts of the present disclosure, and additional features may be included in the semiconductor structure 100, and some of the features described below may be replaced, modified, or eliminated.

The semiconductor structure 100 may include multi-gate devices and may be included in a microprocessor, a memory, and/or other IC devices. For example, the semiconductor structure 100 may be a portion of an IC chip that include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other applicable components, or combinations thereof. The formation of the semiconductor structure 100 will be described in more details below.

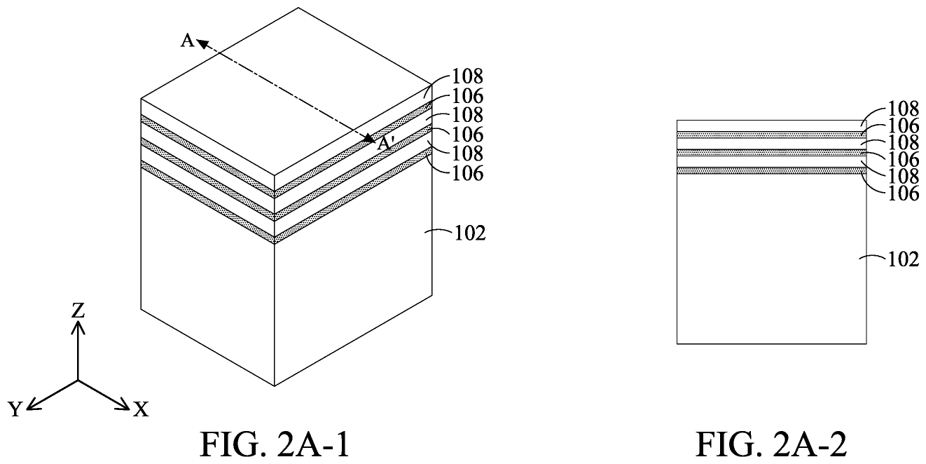

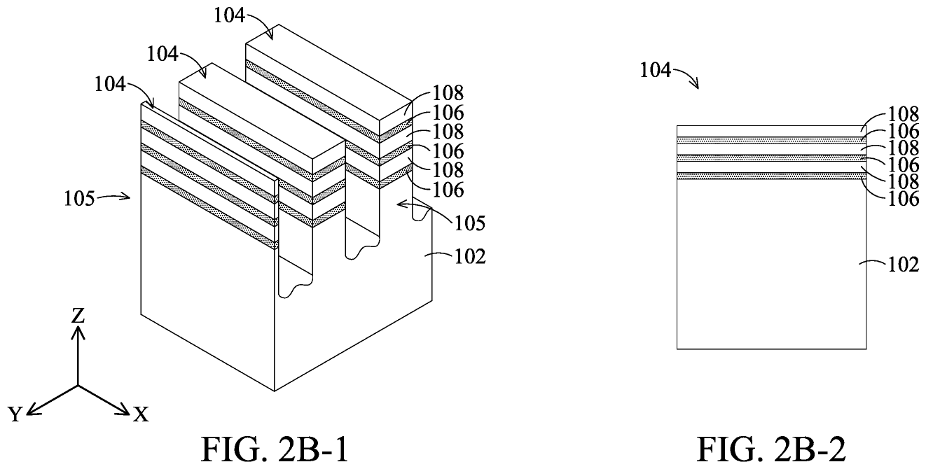

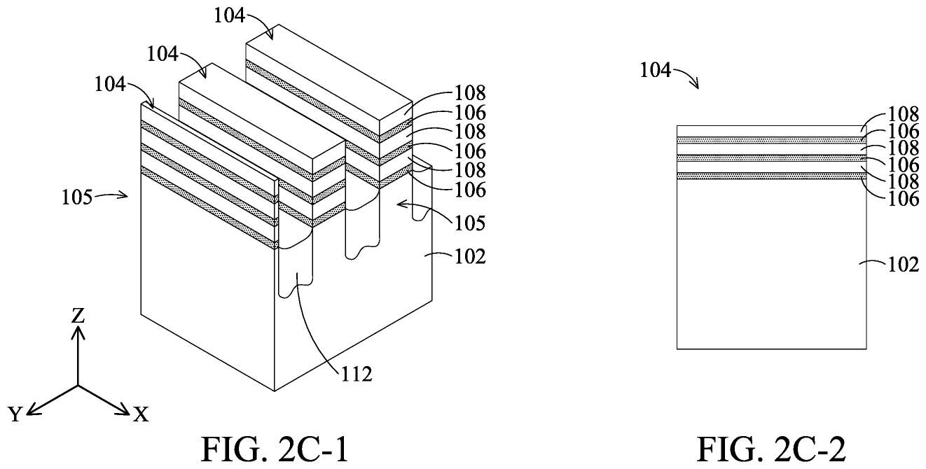

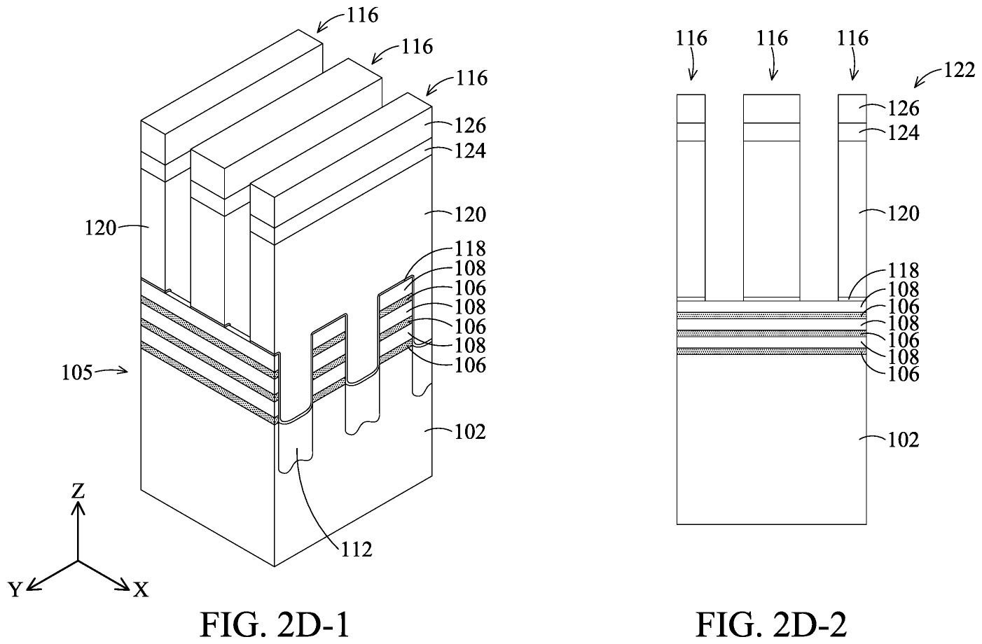

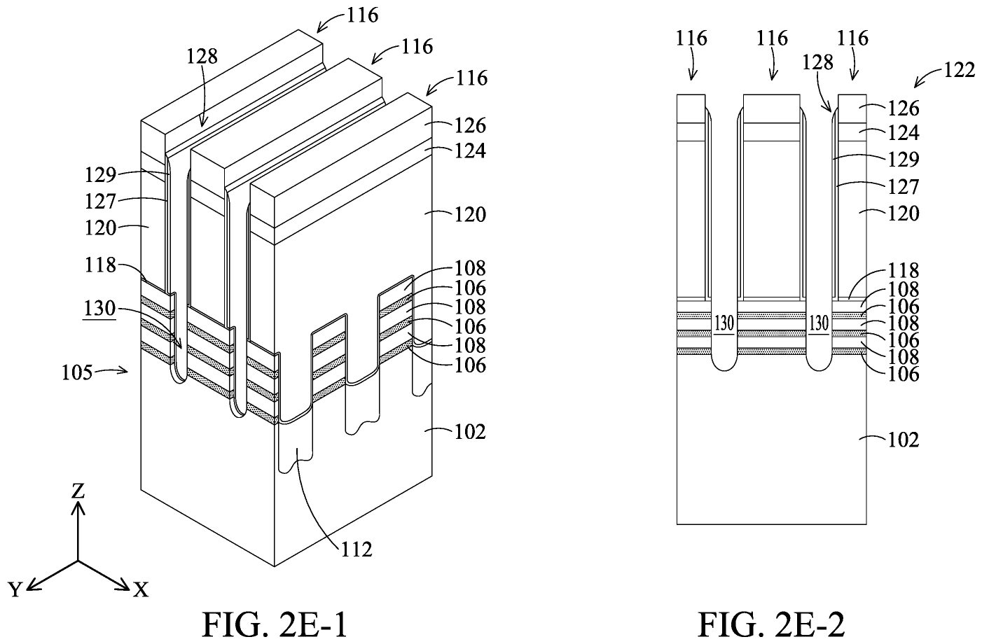

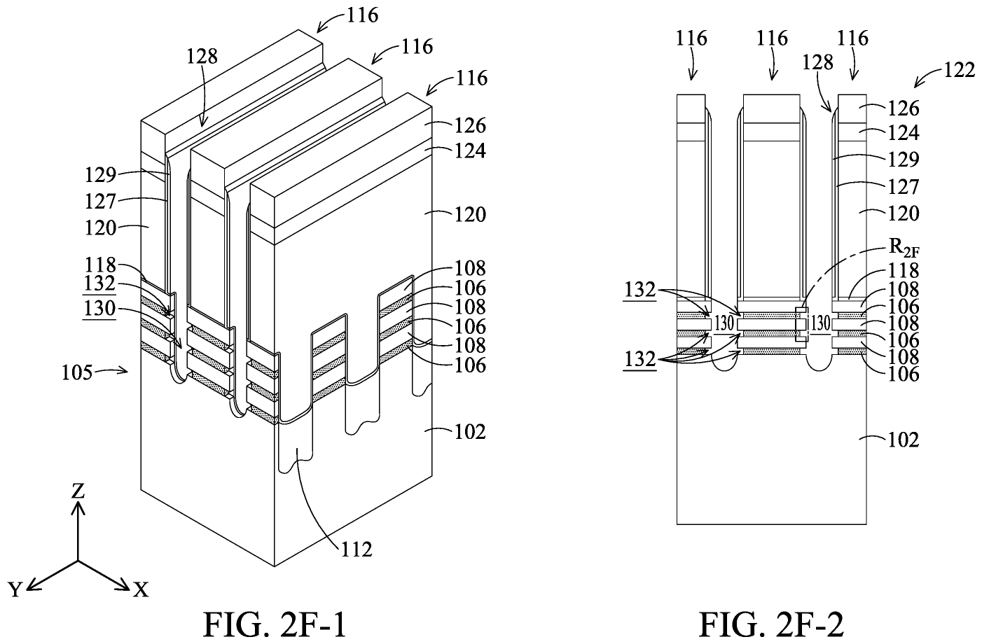

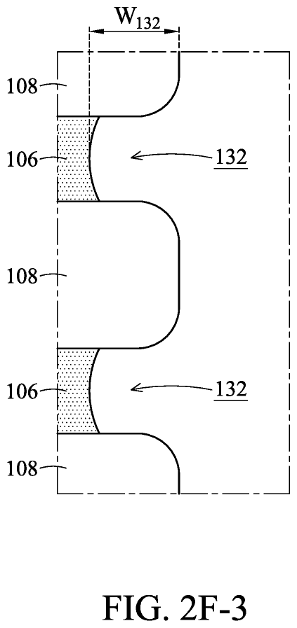

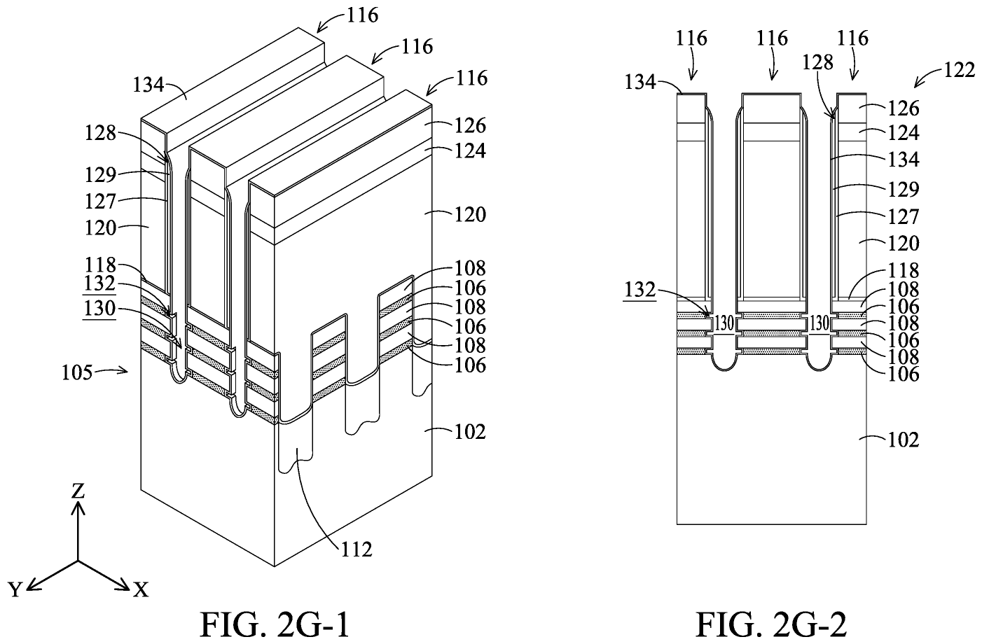

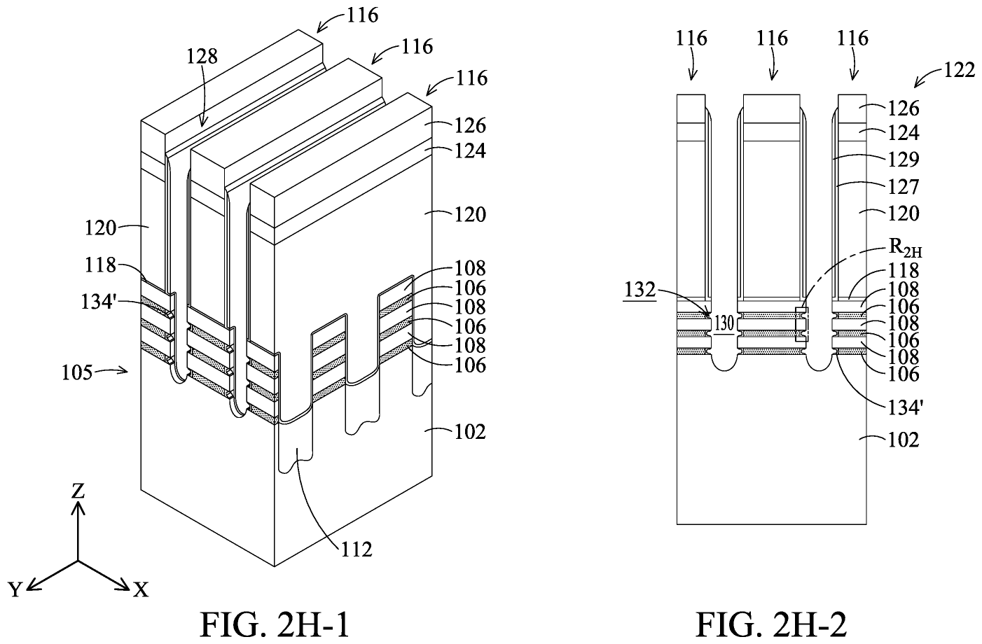

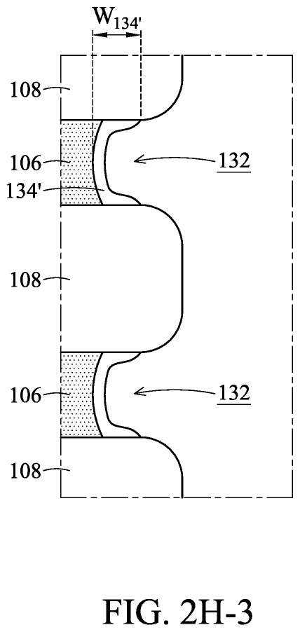

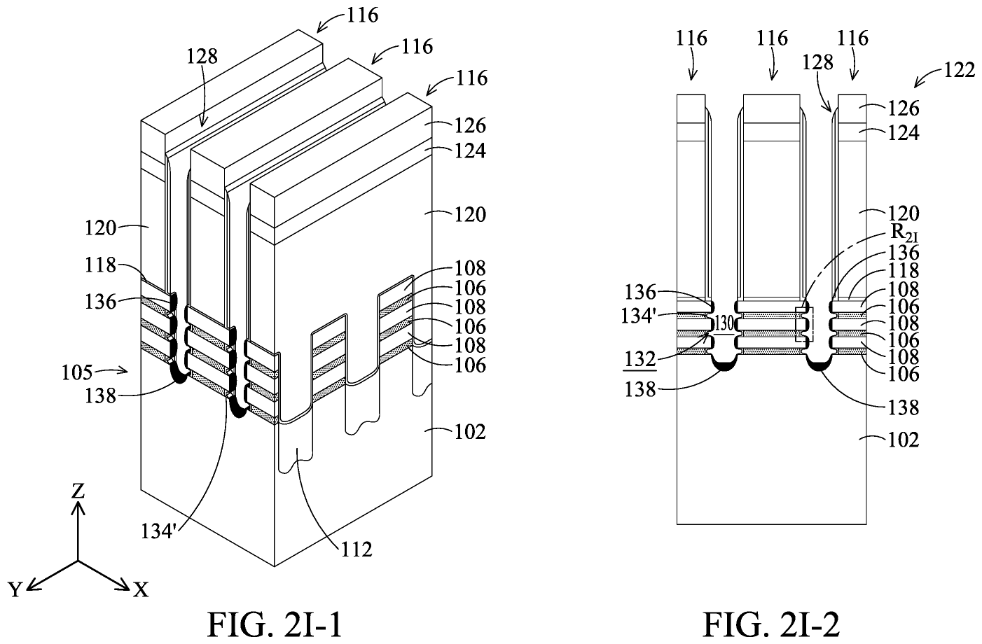

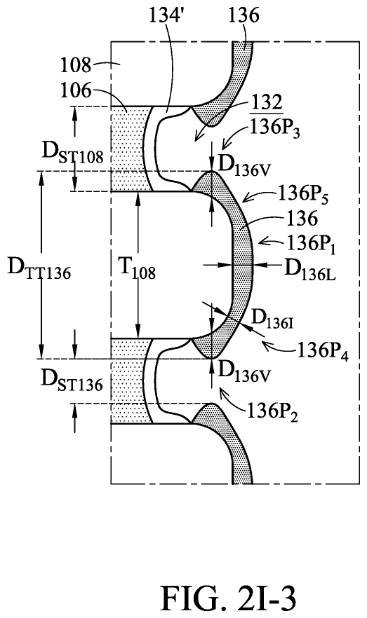

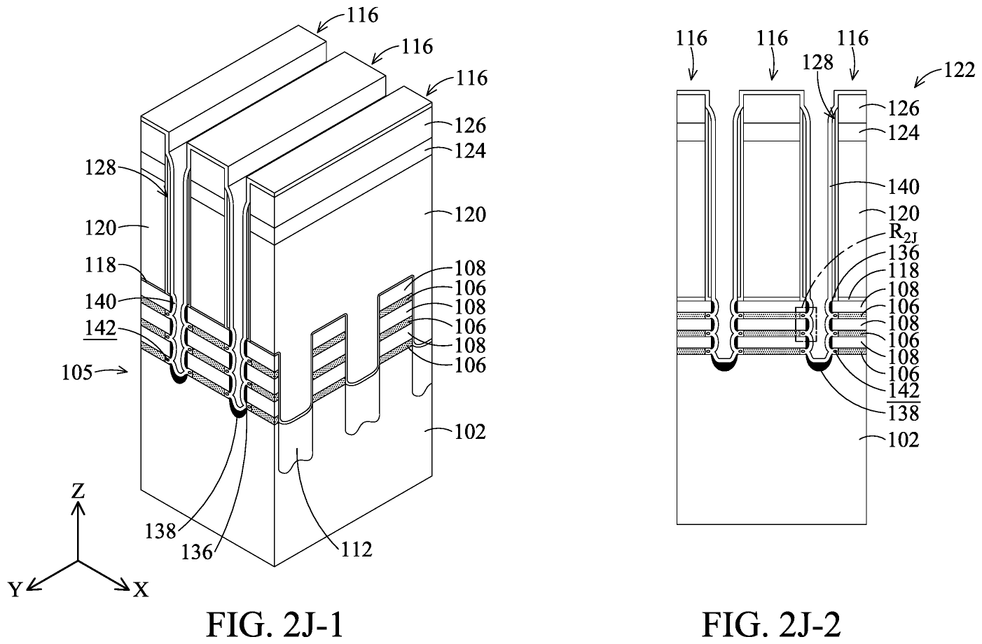

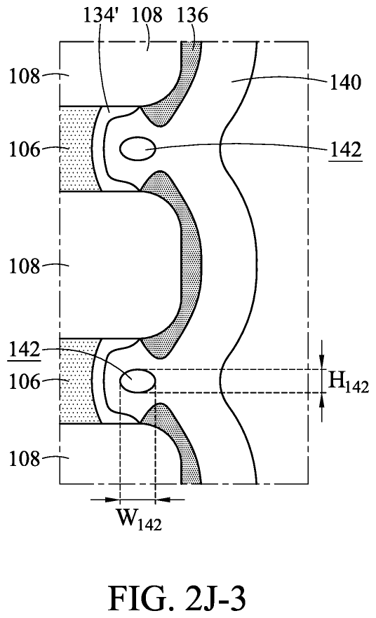

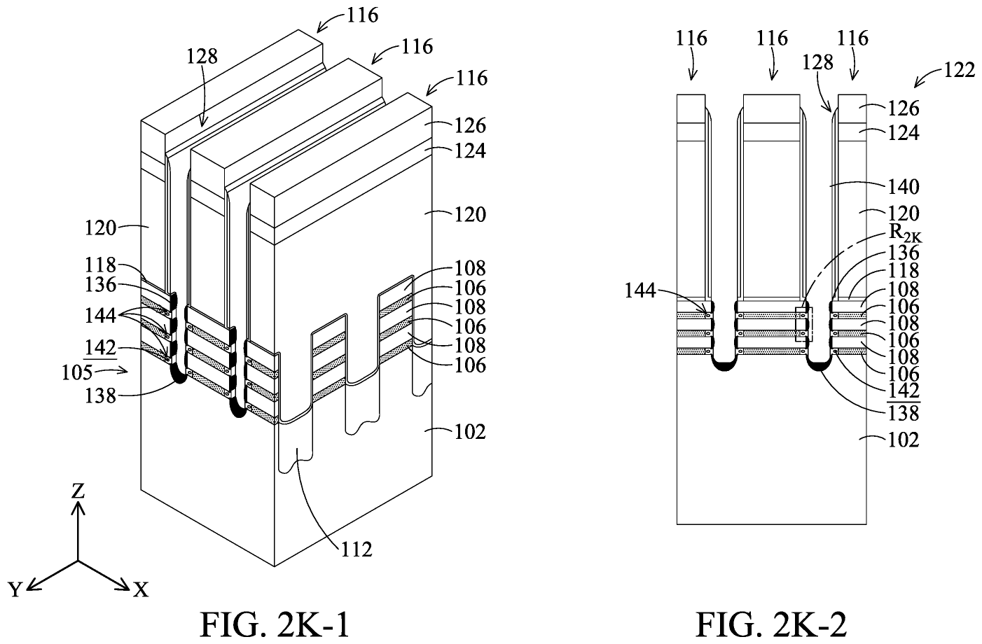

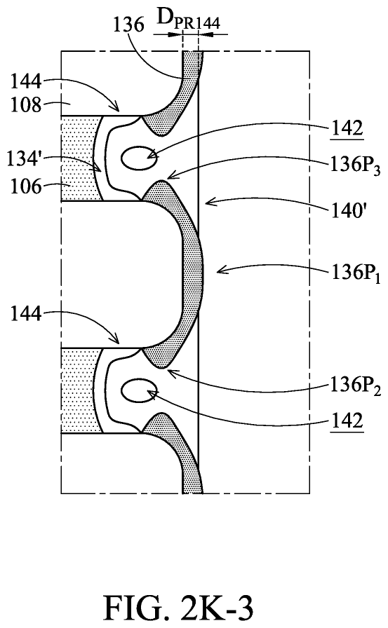

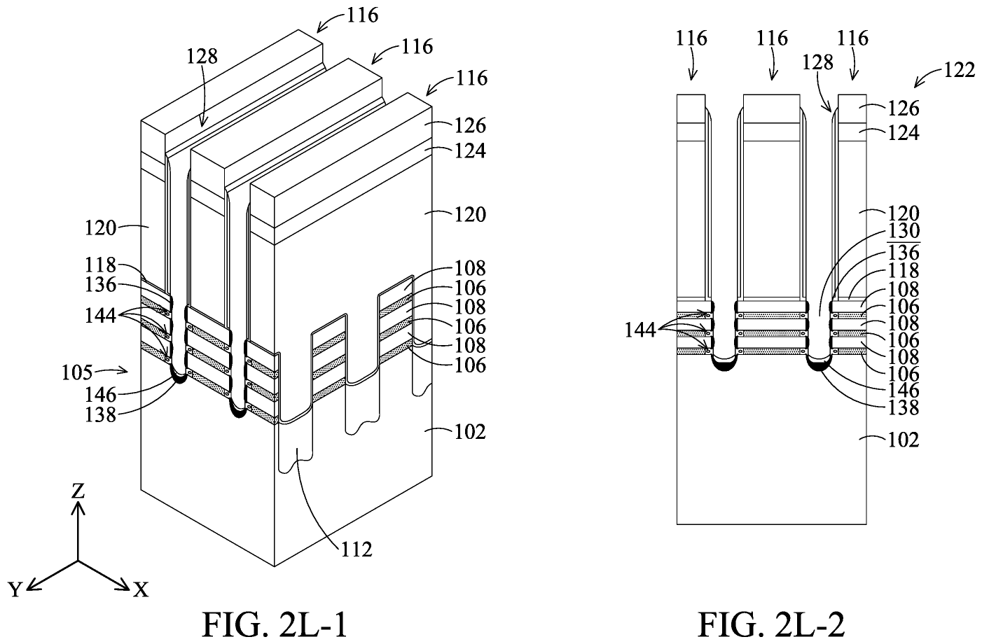

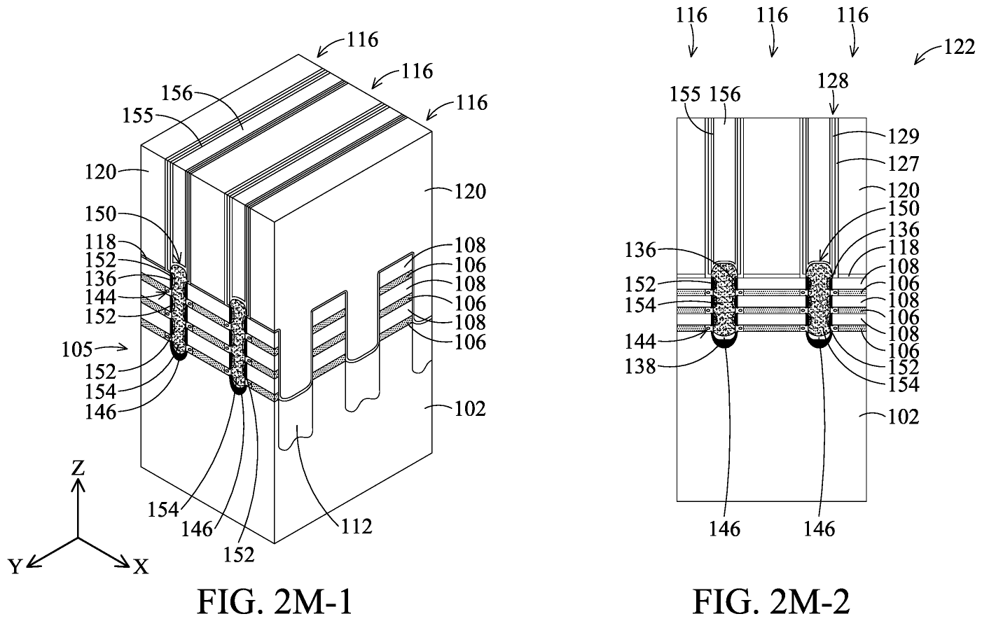

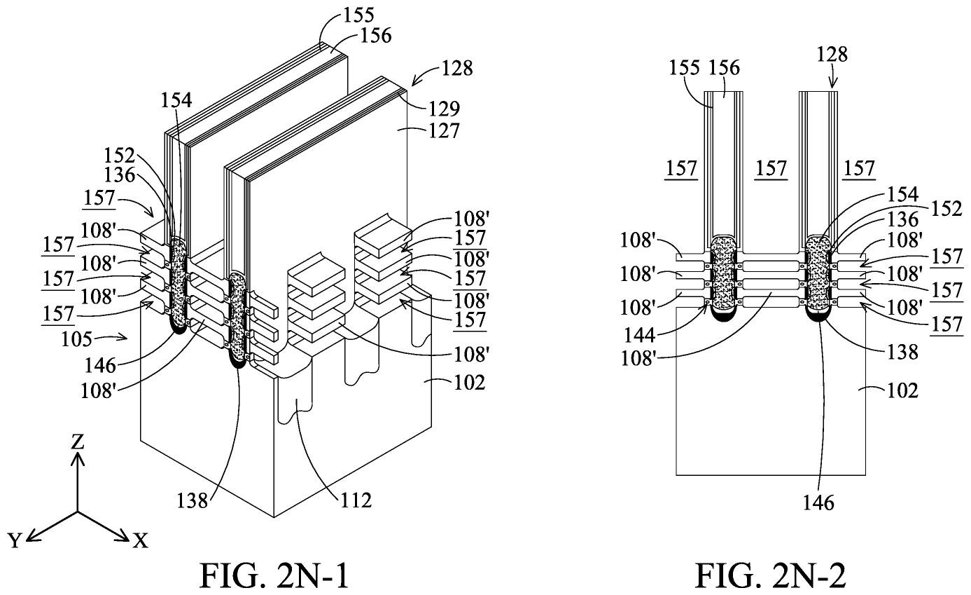

FIGS. 2A-1 to 2O-1 illustrate diagrammatic perspective views of intermediate stages of manufacturing the semiconductor structure 100 shown in region R of FIG. 1 in accordance with some embodiments. FIGS. 2A-2 to 2O-2 illustrate cross-sectional views of the intermediate stages of manufacturing the semiconductor structure 100 shown along line A-A′ of FIG. 1 (also see line A-A′ in FIG. 2A-1) in accordance with some embodiments. For a better understanding of the semiconductor structure 100, the X-Y-Z coordinate reference is provided in the figures. The X-axis and the Y-axis are generally orientated along the lateral (or horizontal) directions that are parallel to the main surface of a substrate 102. The Y-axis is transverse (e.g., substantially perpendicular) to the X-axis. The Z-axis is generally oriented along the vertical direction that is perpendicular to the main surface of the substrate 102 (or the X-Y plane). Some elements in the figures have been simplified for the sake of clarity to better understand the inventive concepts of the present disclosure, and enlarged cross-sectional views may be provided to show the details of the elements.

First, a semiconductor material stack, including first semiconductor material layers 106 and second semiconductor material layers 108, is formed over the substrate 102, as shown in FIGS. 2A-1 and 2A-2 in accordance with some embodiments. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102 to form the semiconductor stack. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are shown in FIGS. 2A-1 and 2A-2, the semiconductor material stack may include more or fewer first semiconductor material layers 106 and second semiconductor material layers 108. For example, the semiconductor material stack may include two to six of the first semiconductor material layers 106 and two to six of the second semiconductor material layers 108.

The first semiconductor material layers 106 and the second semiconductor material layers 108 may be formed using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor material stack over the substrate 102, the semiconductor stack and the upper portion of the substrate 102 are patterned to form fin structures 104 extending along the X direction, as shown in FIGS. 2B-1 and 2B-2 in accordance with some embodiments.

In some embodiments, the fin structures 104 are protruding from the front side of the substrate 102. In some embodiments, the fin structures 104 include base fin structures 105 and the semiconductor material stacks formed over the base fin structure 105. The fin structures 104 may be formed by performing a patterning process. In some embodiments, the patterning process includes forming mask structures over the semiconductor material stack and etching the semiconductor material stack and the underlying substrate 102 through the mask structure. In some embodiments, the mask structures are a multilayer structure including a pad oxide layer and a nitride layer formed over the pad oxide layer. The pad oxide layer may be made of silicon oxide, which may be formed by thermal oxidation or CVD, and the nitride layer may be made of silicon nitride, which may be formed by CVD, such as LPCVD or plasma-enhanced CVD (PECVD).

After the fin structures 104 are formed, an isolation structure 112 is formed around the fin structures 104, as shown in FIGS. 2C-1 and 2C-2 in accordance with some embodiments. In some embodiments, the isolation structure 112 is made of silicon oxide, silicon nitride, silicon oxynitride (SiON), other applicable insulating materials, or a combination thereof. In some embodiments, an isolation liner (not shown) is formed to cover the sidewalls of the base fin structures 105 of the fin structures 104. The isolation liner may be made of a single or multiple dielectric materials. In some embodiments, the isolation liner includes an oxide layer and a nitride layer formed over the oxide layer.

The isolation liner and the isolation structure 112 may be formed by conformally forming a liner layer covering the fin structures 104, forming an insulating material over the liner layer, and recessing the liner layer and the insulating material to form the isolation liner and the isolation structure 112. The isolation structure 112 is configured to electrically isolate active regions (e.g. the fin structures 104) of the semiconductor structure and is also referred to as shallow trench isolation (STI) feature in accordance with some embodiments. In some embodiments, the isolation structure 112 has concave top surfaces.

After the isolation structure 112 is formed, dummy gate structures 116 are formed across the fin structures 104 and extending along the Y direction, as shown in FIGS. 2D-1 and 2D-2 in accordance with some embodiments. The dummy gate structures 116 may be used to define the source/drain regions and the channel regions of the resulting semiconductor structure 100. In some embodiments, each of the dummy gate structures 116 includes a dummy gate dielectric layer 118 and a dummy gate electrode layer 120. In some embodiments, the dummy gate dielectric layer 118 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 118 is formed using thermal oxidation, CVD, ALD, physical vapor deposition (PVD), another suitable method, or a combination thereof. In some embodiments, the dummy gate electrode layer 120 is made of conductive material includes polycrystalline-silicon (poly-Si), poly-crystalline silicon-germanium (poly-SiGe), or a combination thereof. In some embodiments, the dummy gate electrode layer 120 is formed using CVD, PVD, or a combination thereof.

The formation of the dummy gate structures 116 may include conformally forming a dielectric material as the dummy gate dielectric layers 118. Afterwards, a conductive material may be formed over the dielectric material as the dummy gate electrode layers 120, and a hard mask layer 122 may be formed over the conductive material. Next, the dielectric material and the conductive material may be patterned through the hard mask layer 122 to form the dummy gate structures 116. In some embodiments, the hard mask layer 122 includes multiple layers, such as an oxide layer 124 and a nitride layer 126. In some embodiments, the oxide layer 124 is silicon oxide, and the nitride layer 126 is silicon nitride.

After the dummy gate structures 116 are formed, gate spacer layers are conformally formed to cover the gate structures 116 and the fin structures 104, and an etching process is performed to form gate spacers 128 and source/drain recesses 130, as shown in FIGS. 2E-1 and 2E-2 in accordance with some embodiments. More specifically, after the dummy gate structures 116 are formed, spacer layers are conformally deposited over the top and sidewall surfaces of the dummy gate structures 116 and the fin structure 104 and over the top surfaces of the isolation structure 112 in accordance with some embodiments. In some embodiments, the spacer layers include a first spacer layer 127 and a second spacer layer 129. In some other embodiments, only one spacer layer is formed. In some embodiments, the first spacer layers 127 and the second spacer layers 129 are made of different dielectric materials selected from silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the first spacer layers 127 and the second spacer layers 129 are made of different nitride base dielectric materials. In some embodiments, the dielectric constant (k) of the second spacer layer 129 is lower than the dielectric constant (k) of the first spacer layers 127. In some other embodiments, the first spacer layers 127 and the second spacer layers 129 are made of the same dielectric material such as SiN.

Next, the first spacer layers 128 and the second spacer layers 129 are etched to formed gate spacers 128, and the source/drain regions of the fin structure 104 are recessed to form source/drain recesses 130, as shown in FIGS. 2E-1 and 2E-2 in accordance with some embodiments. The gate spacers 128 are configured to maintain integrity of the gate trench during the gate replacement process performed afterwards. In some embodiments, each of the first spacers 127 has a first portion extending along the sidewalls of the dummy gate structure 116 and a second portion formed on (e.g. laterally extending on) the top surface of the topmost layer of the second semiconductor material layers 108. In some embodiments, the first portion and the second portion of the first spacer layer 127 form a L shape in the cross-sectional view, as shown in FIG. 2E-2. In some embodiments, the second spacer layer 129 is vertically above the second portion of the first spacer layer 127. In some embodiments, the second spacer layer 129 is thicker than the first spacer layer 127. In some other embodiments, the first spacer layer 127 is thicker than, or has the same thickness with, the second spacer layer 129.

The portions of the fin structures 104 not covered by the dummy gate structures 116 and the gate spacers 128 are etched to form the source/drain recesses 130 by the etching process in accordance with some embodiments. The etching process may be an anisotropic etching process, such as dry plasma etching, and the dummy gate structure 116 and the gate spacers 128 may be used as etching masks during the etching process. In some embodiments, the isolation structure 112 is also slightly etched during the etching process.

After the source/drain recesses 130 are formed, the first semiconductor material layers 106 exposed by the source/drain recesses 130 are laterally recessed to form notches 132, as shown in FIGS. 2F-1 and 2F-2 in accordance with some embodiments. In some embodiments, an etching process is performed to laterally recess the first semiconductor material layers 106 of the fin structures 104 from the source/drain recesses 130. In some embodiments, during the etching process, the first semiconductor material layers 106 have a greater etching rate (e.g. etching amount) than the second semiconductor material layers 108, thereby forming the notches between the adjacent second semiconductor material layers 108. In some embodiments, portions of the second semiconductor material layers 108 are also etched during the etching process, so that the second semiconductor material layers 108 have rounded corners. In some embodiments, the etching process is dry chemical etching, remote plasma etching, wet chemical etching, another suitable technique, and/or a combination thereof.

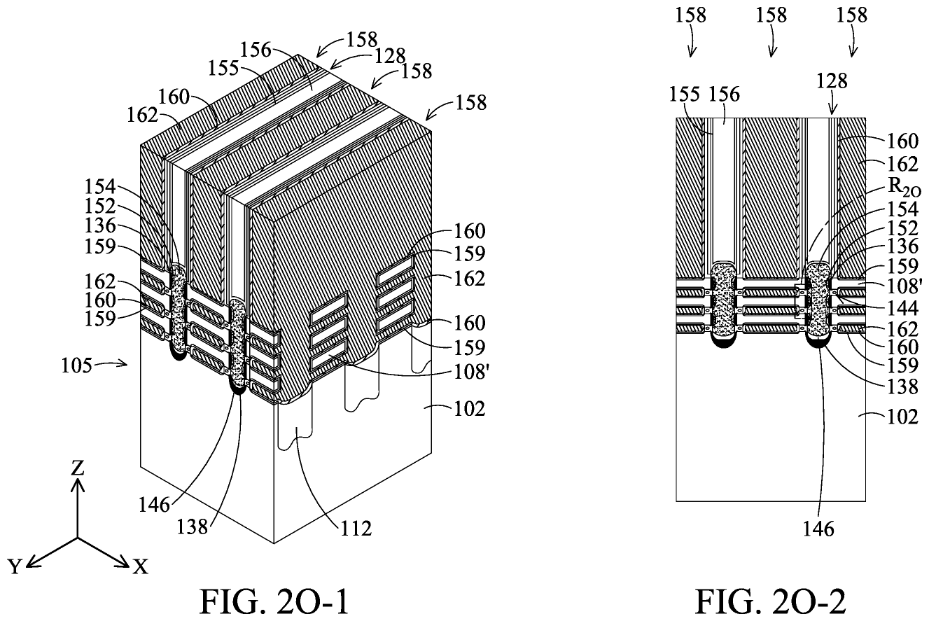

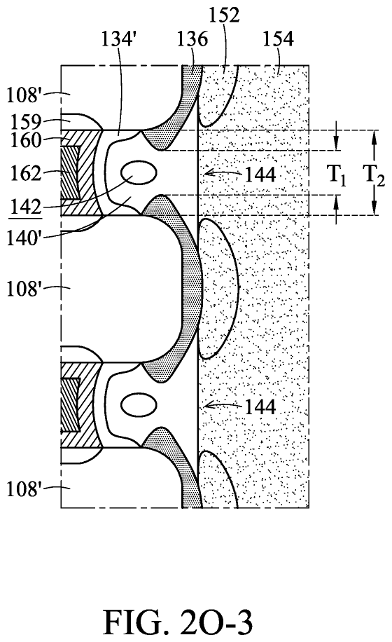

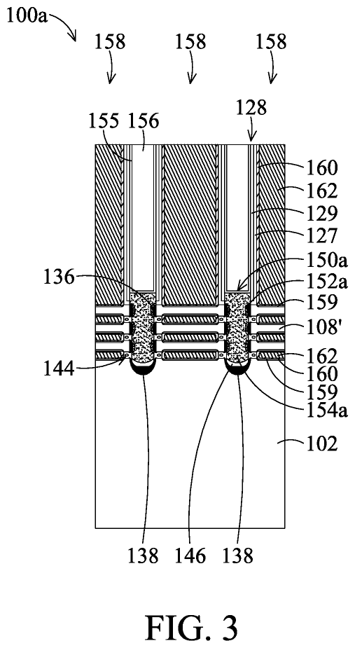

FIG. 2F-3 illustrates an enlarged cross-sectional view of the semiconductor structure 100 of region R_{2F} shown in FIG. 2F-2 in accordance with some embodiments. The notches 132 are configured to provide spaces for forming dielectric structures (e.g. inner spacers) afterwards, and therefore the size of the notches 132 may be controlled. In some embodiments, the notch 132 has a width W₁₃₂ along the X direction in a range from about 4 nm to about 10 nm. The notches 132 should be wide enough so the dielectric structures with multiple layers, including air gaps or a porous material (details will be described later), may be formed therein. On the other hand, the notches 132 should not be too wide, or the space for forming the gate structure in subsequent processes may be reduced.

After the notches 132 are formed, a first inner spacer layer 134 is deposited, as shown in FIGS. 2G-1 and 2G-2 in accordance with some embodiments. More specifically, the first inner spacer layer 134 is formed in the notches 132 and in the source/drain recesses 130 and also covering the dummy gate structures 116 and the gate spacers 128 in accordance with some embodiments. In some embodiments, the first inner spacer layer 134 is made of a low k dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the first inner spacer layer 134 has a thickness in a range from about 1 nm to about 3 nm. The first inner spacer layer 134 should be thick enough so it will not be breakthrough during the etching process for removing the first semiconductor material layers 106 in the channel regions in subsequent processes. On the other hand, the first inner layer 134 should not be too thick, or the notches 132 may be completely filled with the first inner spacer layer 134, such that there may not be enough space for forming another inner spacer layer with air gaps or porous materials (the details will be described afterwards).

After the first inner spacer layer 134 is formed, a trimming process is performed to form first inner spacers 134′, as shown in FIGS. 2H-1 and 2H-2 in accordance with some embodiments. More specifically, an etching process may be performed onto the first inner spacer layer 134 to remove the first inner spacer layer 134 formed over the dummy gate structures 116, the gate spacers 128, and the source/drain recesses 130 in accordance with some embodiments. Accordingly, the first inner spacers 134′ are formed in the notches 132 in accordance with some embodiments. In some embodiments, the trimming process is a dry etching process. In some embodiments, the dry etching process includes using fluorine-containing gas, such as CH₃F or CF₄.

FIG. 2H-3 illustrates an enlarged cross-sectional view of the semiconductor structure 100 of region R_{2H} shown in FIG. 2H-2 in accordance with some embodiments. In some embodiments, the first inner spacers 134′ cover the inner sidewalls of the notches 132 and partially cover the top and bottom surfaces of the notches 132 (i.e. the top and bottom surfaces of the second semiconductor material layers 108 exposed by the notches 132). In some embodiments, the first inner spacers 134′ completely overlap the second semiconductor material layers 108. In some embodiments, the top and bottom surfaces of the second semiconductor material layers 108 exposed by the notches 132 are not completely covered by the first inner spacers 134′, such that portions of the second semiconductor material layers 108 are stilled exposed by the notches 132 after the first inner spacers 134′ are formed. That is, the first inner spacer 134′ has a width 134′ smaller than the width W₁₃₂ of the notch 132 shown in FIG. 2F-3, and therefore the edges of the first inner spacers 134′ are indented from the edges of the second semiconductor material layers 108 in the X direction.

After the first inner spacers 134′ are formed, epitaxial layers 136 are formed on the second semiconductor material layers 108 and bottom epitaxial layers 138, as shown in FIGS. 2I-1 and 2I-2 in accordance with some embodiments. In some embodiments, the epitaxial layers 136 and the bottom epitaxial layers 138 are formed using an epitaxial growth process, such as MBE, MOCVD, VPE, other applicable epitaxial growth process, or a combination thereof.

More specifically, the epitaxial layers 136 and the bottom epitaxial layers 138 are both un-doped Si layers and are formed from the exposed portions of the second semiconductor material layers 108 and the exposed portion of the base fin structures 105 exposed by the source/drain recesses 130 respectively in accordance with some embodiments. Generally, the un-doped Si layers have different growth rate at different orientations. For example, the growth rate at (1, 0, 0) is greater than that at (1, 1, 0), and the growth rate at (1, 1, 0) is greater than that at (1, 1, 1). Accordingly, the epitaxial layers 136 have different growth rate and therefore, have different thicknesses at different portions. In some embodiments, the epitaxial layers 136 are facet-like structure with angle to the second semiconductor material layers 108 of about 45° to about 55°.

FIG. 2I-3 illustrates an enlarged cross-sectional view of the semiconductor structure 100 of region R_{2I} shown in FIG. 2I-2 in accordance with some embodiments. In some embodiments, most of the epitaxial layers 136 includes a first portion 136P₁ laterally extending from the exposed sidewalls of the second semiconductor material layers 108, a second portion 136P₂ vertically extending downwardly from the exposed bottom surfaces of the second semiconductor material layers 108, and a third portion 136P₃ vertically extending upwardly from the exposed top surfaces of the second semiconductor material layers 108. Meanwhile, the epitaxial layers 136 formed over the topmost second semiconductor material layers 108 have the first portion 136P₁ laterally extending from the exposed sidewalls of the second semiconductor material layers 108 and the second portions 136P₂ vertically extending upwardly from the exposed bottom surfaces of the second semiconductor material layers 108 but do not have the third portion 136P₃ since the top surface of the topmost second semiconductor material layer 108 is covered by the gate spacers 128 in accordance with some embodiments. In some embodiments, the epitaxial layers 136 further have fourth portions 136P₄ and fifth portions 136P₅ grown from the corners portions of the second semiconductor material layers 108.

Each of the epitaxial layers 136 may have a lateral dimension D_{136L} (e.g. a dimension of the first portion 136P₁ in X direction), a vertical dimension D_{136V} (e.g. a dimension of the second portion 136P₂ and/or third portion 136P₃ in Z direction), and an inclined dimension D_{136I} (e.g. a dimension of the fourth portions 136P₄ and the fifth portions 136P₅ in a direction between X direction and Z direction) as shown in FIG. 2I-3. In some embodiments, the inclined dimension D_{136I} is smaller than both the lateral dimension D_{136L} and the vertical dimension D_{136V}. In some embodiments, the lateral dimension D_{136L} is smaller than the vertical dimension D_{136V}. In some embodiments, the lateral dimension D_{136L} is in a range from about 1 nm to about 3 nm. In some embodiments, the vertical dimension D_{136V} is in a range from about 1 nm to about 3 nm. In some embodiments, the inclined dimension D_{136I} is in a range from about 0.5 nm to about 2 nm.

Since the second portions 136P₂ and the third portion 136P₃ are vertically extending from the bottom and top surfaces of the second semiconductor material layers 108, the epitaxial layers 136 has a vertical dimension D_{TT136} being greater than a thickness T₁₀₈ of the second semiconductor material layer 108. Accordingly, the vertical distance D_{ST136} between the neighboring second portions 136P₂ and third portion 136P₃ of the epitaxial layers 136 is smaller than the vertical distance DST 108 between the neighboring second semiconductor material layers 108 (e.g. the thickness of the first semiconductor material layer 106) in accordance with some embodiments. That is, the openings of the notches 132 are shrunken after the epitaxial layers 136 are formed.

After the epitaxial layers 136 and the bottom epitaxial layers 138 are formed, a second inner spacer layer 140 is deposited, as shown in FIGS. 2J-1 and 2J-2 in accordance with some embodiments. More specifically, the second inner spacer layer 140 is formed in the notches 132 and in the source/drain recesses 130 and also covering the dummy gate structures 116 and the gate spacers 128 in accordance with some embodiments. More specifically, the second inner spacer layer 140 covers the first inner spacers 134′ in the notches 132, the epitaxial layers 136 over the second semiconductor material layers 108, and the bottom epitaxial layers 138 in the source/drain recesses 130 in accordance with some embodiments.

In some embodiments, the second inner spacer layer 140 is made of a low k dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the second inner spacer layer 140 is made of a dielectric material the same as that the first inner spacer layer 134 is made of. In some embodiments, the second inner spacer layer 140 and the first inner spacer layer 134 are made of different dielectric materials. In some embodiments, the notches 132 are substantially filled with the second inner spacer layer 140.

FIG. 2J-3 illustrates an enlarged cross-sectional view of the semiconductor structure 100 of region R_{2J} shown in FIG. 2J-2 in accordance with some embodiments. As described previously, the opening of the notches 132 have been shrunken after the formation of the epitaxial layers 136. Therefore, although the notches 132 are substantially filled with the second inner spacer layer 140, air gaps 142 are formed in the second inner spacer layer 140, as shown in FIG. 2J-2 in accordance with some embodiments. The existence of the air gaps 142 may be beneficial to the k value of the resulting dielectric structures (i.e. with lower k value), and the capacitance of the resulting device may therefore be reduced.

In some embodiments, the air gaps 142 are completely vertically under (i.e. overlap) the second semiconductor material layers 108. That is, the air gaps 142 do not laterally protrude from the notches 132 and the second semiconductor material layers 108. In some embodiments, the air gap 142 has a height H₁₄₂ in a range from about 2 nm to about 6 nm. In some embodiments, the air gap 142 has a width W₁₄₂ in a range from about 2 nm to about 4 nm. The size of the air gap 142 should be great enough to have a lower k value. On the other hand, the air gap 142 should not be too large, or it may be exposed in subsequent etching processes (e.g. the etching process for removing the first semiconductor material layers 106), resulting in increasing the risk of the circuit short of the device.

After the second inner spacer layer 140 is formed, a trimming process is performed to form second inner spacers 140′, as shown in FIGS. 2K-1 and 2K-2 in accordance with some embodiments. More specifically, an etching process may be performed onto the second inner spacer layer 140 to remove the second inner spacer layer 140 formed over the dummy gate structures 116, the gate spacers 128, and the source/drain recesses 130 in accordance with some embodiments. Accordingly, the second inner spacers 140′ are formed next to the first inner spacers 134′ in the notches 132 in accordance with some embodiments. In some embodiments, the trimming process is a dry etching process. In some embodiments, the dry etching process includes using fluorine-containing gas, such as CH₃F or CF₄.

FIG. 2K-3 illustrates an enlarged cross-sectional view of the semiconductor structure 100 of region R_{2K} shown in FIG. 2K-2 in accordance with some embodiments. In some embodiments, the second inner spacers 140′ cover the sidewalls of the first inner spacers 134′. In addition, the second inner spacers 140′ partially cover the epitaxial layers 136, as shown in FIG. 2K-3 in accordance with some embodiments. Since the second portions 136P₂ and the third portion 136P₃ of the epitaxial layers 136 vertically extend into the notches 132, the second portions 136P₂ and the third portion 136P₃ also extend into the second inner spacers 140′ in accordance with some embodiments.

The first inner spacers 134′ and the second inner spacers 140′ may be seen as dielectric structures 144, which are configured to separate the gate structures and the source/drain structures formed afterwards. As described previously, the air gaps 142 are embedded in the second inner spacers 140′ of the dielectric structures 144, so that the k value of the dielectric structures 144 may be relatively low. In some embodiments, the ratio of the size of the air gap 142 to the size of the dielectric structure 144 is in a range from about 20% to about 60%, and the capacitance/performance of the resulting semiconductor device may be improved for about 3% to about 10%.

In some embodiments, the second inner spacers 140′ of the dielectric structures 144 laterally protrude from the sidewalls of the second semiconductor material layers 108. In some embodiments, the second inner spacers 140′ of the dielectric structures 144 laterally protruding from the sidewalls of the second semiconductor material layers 108 for a distance D_{PR144} no more than 2 nm.

After the dielectric structures 144 are formed, bottom isolation structure 146 are formed over the bottom epitaxial layers 138 in the source/drain recesses 130, as shown in FIGS. 2L-1 and 2L-2 in accordance with some embodiments. The bottom isolation structures 146 are configured to prevent electrical leakage under source/drain structures formed afterwards. In some embodiments, the bottom isolation structures 146 partially cover the sidewalls of the bottommost dielectric structures 144. In some embodiments, bottom isolation structures 146 continuously extend from one bottommost dielectric structure 144 to another bottommost dielectric structure 144, as shown in FIG. 2L-2.

In some embodiments, the bottom isolation structures 146 are made of a dielectric material. In some embodiments, the bottom isolation structures 146 are made of a dielectric material having a k value greater than 7, such as HfO₂, ZrO₂, HfAlOₓ, HfSiOₓ, Al₂O₃, or the like. In some embodiments, the bottom isolation structures 146 and the second inner spacers 140′ are made of different materials. In some other embodiments, the bottom isolation structures 146 are made of a dielectric material having a k value lower than 7, such as SiO₂, SiN, SiCN, SiOC, SiOCN, or the like. In some embodiments, the bottom isolation structures 146 and the second inner spacers 140′ are made of the same material. The bottom isolation structures 146 may be formed by depositing a dielectric material in the source/drain recesses 130 and recessing the dielectric material to form the bottom isolation structures 146 over the bottom epitaxial layers 138.

Afterwards, source/drain structures 150 are formed in the source/drain recesses 130, as shown in FIGS. 2M-1 and 2M-2 in accordance with some embodiments. In some embodiments, the source/drain structures 150 are formed using an epitaxial growth process, such as MBE, MOCVD, VPE, other applicable epitaxial growth process, or a combination thereof. In some embodiments, the source/drain structures 150 are made of any applicable material, such as Ge, Si, GaAs, AlGaAs, SiGe, GaAsP, SiP, SiC, SiCP, or a combination thereof. In some embodiments, the source/drain structures 150 are in-situ doped during the epitaxial growth process. For example, the source/drain structures 150 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain structures 150 are doped in one or more implantation processes after the epitaxial growth process. The source/drain structures (or region(s)) may refer to a source or a drain, individually or collectively dependent upon the context

In some embodiments, each of the source/drain structures 150 includes first portions 152 and a second portion 154. In some embodiments, the first portions 152 are grown from the exposed portions of the epitaxial layers 136, and the second portions 154 are formed over the first portions 152, and the source/drain recesses 130 are completely filled with the second portions 154. In some embodiments, the first portions 152 include separated portions grown from each of the exposed sidewalls of epitaxial layers 136. In some embodiments, the first portions 152 are in direct contact with the dielectric structures 144. In addition, the topmost portions of the first portions 152 of the source/drain structures 150 are in direct contact with the gate spacers 128 in accordance with some embodiments. In some embodiments, the second portions 154 are formed in the source/drain recesses 130 around the first portions 152. In some embodiments, the second portions 154 are also in direct contact with the dielectric structures 144 and the gate spacers 128. In some embodiments, the source/drain structures 150 are N epitaxial structures with the first portions 152 being made of SiAs, and the second portions 154 being made of SiP. In some embodiments, the second portions 154 of the source/drain structures 150 have thicker middle portions and thinner edge portions.

After the source/drain structures 150 are formed, a contact etch stop layer (CESL) 155 is conformally formed to cover the source/drain structures 150 and dummy gate structures 116, and an interlayer dielectric (ILD) layer 156 is formed over the contact etch stop layers 155, as shown in FIGS. 2M-1 and 2M-2 in accordance with some embodiments.

In some embodiments, the contact etch stop layer 155 is made of a dielectric material, such as silicon nitride, silicon oxide, silicon oxynitride, another suitable dielectric material, or a combination thereof. The dielectric material for the contact etch stop layers 155 may be conformally deposited over the semiconductor structure by performing CVD, ALD, other application methods, or a combination thereof.

The interlayer dielectric layer 156 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 156 may be formed by chemical vapor deposition (CVD), physical vapor deposition, (PVD), atomic layer deposition (ALD), or other applicable processes.

After the contact etch stop layer 155 and the interlayer dielectric layer 156 are deposited, a planarization process such as CMP or an etch-back process is performed until the gate electrode layers 120 of the dummy gate structures 116 are exposed in accordance with some embodiments.

Next, the dummy gate structures 116 and the first semiconductor material layers 106 of the fin structures 104 are removed to form gate trenches 157, as shown in FIGS. 2M-1 and 2M-2 in accordance with some embodiments. More specifically, the dummy gate structures 116 and the first semiconductor material layers 106 of the fin structures 104 are removed to form channel members 108′ with the second semiconductor material layers 108 of the fin structures 104 respectively, in accordance with some embodiments.

The removal process may include one or more etching processes. For example, when the dummy gate electrode layers 120 are polysilicon, a wet etchant such as a tetramethylammonium hydroxide (TMAH) solution may be used to selectively remove the dummy gate electrode layers 120. Afterwards, the dummy gate dielectric layers 118 may be removed using a plasma dry etching, a dry chemical etching, and/or a wet etching. The first semiconductor material layers 106 may then be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

In some embodiments, a trimming process is performed to trim (e.g. slightly etched) the second semiconductor material layers 108 and the base fin structures 105. Accordingly, the resulting channel members 108′ are narrower at the channel regions than those under the gate spacers 128 in accordance with some embodiments. In addition, the isolation structure 112 under the dummy gate structures 116 is also partially removed during the trimming process, and therefore the isolation structure 112 have recessed portions exposed by the gate trenches 157.

As shown in FIG. 2N-1, the sidewalls of the first inner spacers 134 are exposed by the gate trenches 157 in accordance with some embodiments. In some embodiments, the first inner spacers 134′ are also slight etched during the etching process for removing the first semiconductor material layers 106. Accordingly, the first inner spacers 134′ should be thick enough, so that the air gaps 142 in the second inner spacers 140′ will not be exposed when forming the channel members 108′. If the air gaps 142 are exposed from the channel regions, the conductive materials for forming the gate structures may be formed in the air gaps 142, resulting in relatively high risk of short circuit.

Next, gate structures 158 are formed in the gate trenches 157, as shown in FIGS. 2O-1 and 2O-2 in accordance with some embodiments. More specifically, the gate structures 158 wraps around the channel members 108′ in accordance with some embodiments. In some embodiments, each of the gate structures 158 includes an interfacial layer 159, a gate dielectric layer 160, and a gate electrode layer 162. In some embodiments, the interfacial layer 159 is an oxide layer formed around the channel members 108′ and on the exposed portions of the base fin structures 105. In some embodiments, the interfacial layer 159 is formed by performing a thermal process.

In some embodiments, the gate dielectric layer 160 is formed over the interfacial layer 159, so that the channel members 108′ are surrounded (e.g. wrapped) by the gate dielectric layer 160. In addition, the gate dielectric layer 160 also covers the sidewalls of the gate spacers 128 and the dielectric structures 144 in accordance with some embodiments. In some embodiments, the gate dielectric layers 160 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, other applicable high-k dielectric materials, or a combination thereof. In some embodiments, the gate dielectric layers 160 are formed using CVD, ALD, other applicable methods, or a combination thereof.

The semiconductor structure 100 includes channel members 108′ suspended over base fin structure 105 over the substrate 102 and vertically spaced apart from each other, as shown in FIG. 2O-1 in accordance with some embodiments. In addition, the gate structures 158 longitudinally oriented in Y direction and wraps around the channel members 108′ in accordance with some embodiments. The source/drain structures 150 are attached to the channel members 108′ at opposite sides of the gate structures 158, and the dielectric structures 144 are sandwiched between the gate structures 158 and the source/drain structures 150 in accordance with some embodiments.

FIG. 2O-3 illustrates an enlarged cross-sectional view of the semiconductor structure 100 of region R_{2O} shown in FIG. 2O-2 in accordance with some embodiments. As described previously, each of the dielectric structures 144 includes a periphery region and a core region surrounded by the periphery region, and the periphery region includes the first inner spacer 134′ and the second inner spacer 140′, and the core region includes the air gap 142 embedded in the second inner spacer 140′ in accordance with some embodiments. Since the dielectric structures 144 include the air gaps 142, the k value of the dielectric structures 144 may be reduced. In some embodiments, the first inner spacers 134′ of the dielectric structures 144 are in direct contact with the gate dielectric layers 160 of the gate structures 158. In addition, the second inner spacers 140′ of the dielectric structures 144 are in direct contact with the source/drain structures 150.

As shown in FIG. 2O-3, the dielectric structure 144 is encircled by the channel member 108′, the gate structures 156, and the source/drain structures 150 in accordance with some embodiments. In addition, the epitaxial layers 136 partially extend into the dielectric structures 144 and are in direct contact with the first inner spacers 134′ and the second inner spacers 140′ in accordance with some embodiments. However, the epitaxial layers 136 are spaced apart from the air gaps 142 in accordance with some embodiments. In some embodiments, the first inner spacers 134′ and the second inner spacers 140′ are made of the same material, and therefore no interface is shown between the first inner spacers 134′ and the second inner spacers 140′.

In some embodiments, the dielectric structure 144 has a first thickness T₁ between the extending portion of the epitaxial layers 136 (e.g. the same as the distance D_{ST136} between the neighboring second portion 136P₂ and third portion 136P₃) and a second thickness T₂ between the neighboring channel members 108′, and the first thickness T₁ is smaller than the second thickness T₂.

FIG. 3 illustrates a cross-sectional view of a semiconductor structure 100a in accordance with some embodiments. The semiconductor structure 100a may be similar to the semiconductor structure 100 described previously, except the shape of the source/drain structures are different from that in the semiconductor structure 100 in accordance with some embodiments. Processes and materials for forming the semiconductor structure 100a may be similar to, or the same as, those for forming the semiconductor structure 100 described previously and are not repeated herein.

More specifically, source/drain structures 150a are formed in the source/drain recesses (e.g. the source/drain recesses 130 shown in FIG. 2L-2), as shown in FIG. 3 in accordance with some embodiments. In some embodiments, the source/drain structures 150a are formed using an epitaxial growth process, such as MBE, MOCVD, VPE, other applicable epitaxial growth process, or a combination thereof. In some embodiments, the source/drain structures 150a are made of any applicable material, such as Ge, Si, GaAs, AlGaAs, SiGe, GaAsP, SiP, SiC, SiCP, or a combination thereof. In some embodiments, the source/drain structures 150a are in-situ doped during the epitaxial growth process. For example, the source/drain structures 150a may be the epitaxially grown SiGe doped with boron (B). In some embodiments, the source/drain structures 150a are doped in one or more implantation processes after the epitaxial growth process. The source/drain structures (or region(s)) may refer to a source or a drain, individually or collectively dependent upon the context

In some embodiments, each of the source/drain structures 150a includes first portions 152a and a second portion 154a. In some embodiments, the first portions 152a are grown from the exposed portions of the epitaxial layers 136, and the second portions 154a are formed over the first regions 152a, and the source/drain recesses are completely filled with the second portions 154a. In some embodiments, the first portions 152a include separated portions grown from each of the exposed sidewalls of epitaxial layers 136. In some embodiments, the first portions 152a are in direct contact with the dielectric structures 144. In addition, the topmost portions of the first portions 152a of the source/drain structures 150a are in direct contact with the gate spacers 128 in accordance with some embodiments. In some embodiments, the second portions 154a are formed in the source/drain recesses around the first portions 152a. In some embodiments, the second portions 154a are also in direct contact with the dielectric structures 144 and the gate spacers 128. In some embodiments, the source/drain structures 150a are P epitaxial structures, the first portions 152 are made of SiB, and the second portions 154 are made of SiGe.

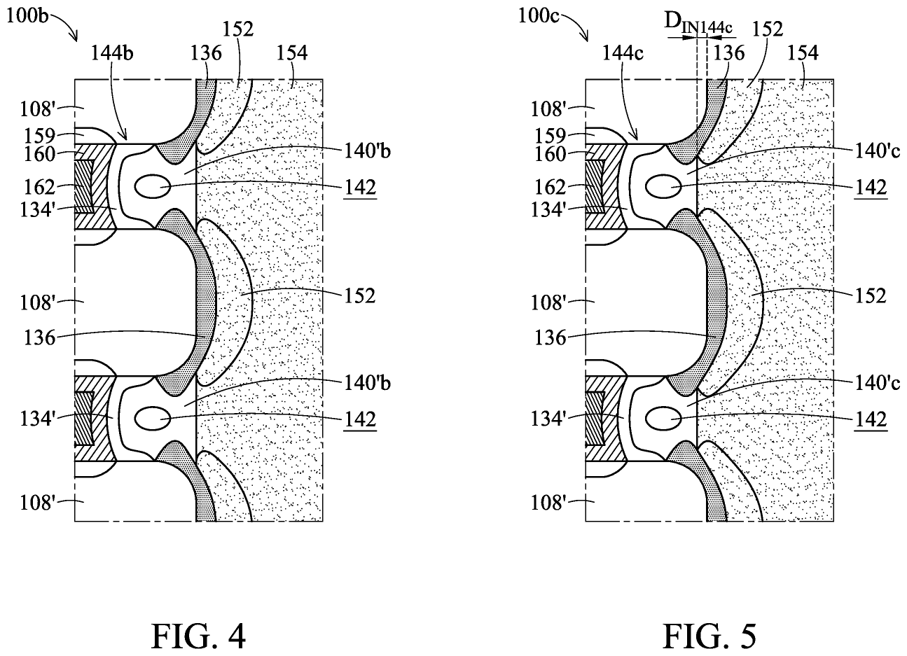

FIG. 4 illustrates an enlarged cross-sectional view of a semiconductor structure 100b in accordance with some embodiments. The semiconductor structure 100b may be similar to the semiconductor structure 100 described previously, except the size of the dielectric structures are different from that semiconductor structure 100 in the in accordance with some embodiments. Processes and materials for forming the semiconductor structure 100b may be similar to, or the same as, those for forming the semiconductor structure 100 described previously and are not repeated herein. For example, the enlarged cross-sectional view shown in FIG. 4 may be similar to that shown in FIG. 2O-3, and other elements in the semiconductor structure 100b not shown in FIG. 4 may be similar to, or the same as, those shown in FIGS. 2O-1, 2O-2, and 2O-3 described previously in accordance with some embodiments.

More specifically, the semiconductor structure 100b includes dielectric structures 144b, and each of the dielectric structures 144b includes the first inner spacer 134′ and a second inner spacer 140′b in accordance with some embodiments. The formation of the second inner spacer 140′b may be the same as that of the second inner spacer 140′ described above, except after the trimming process for trimming the second inner spacer layer, the outer sidewall of the second inner spacer 140′b does not laterally extend outside the edges of the channel members 108′, as shown in FIG. 4 in accordance with some embodiments. In some embodiments, the outer sidewall of the second inner spacer 140′b is substantially aligned with the edges of the channel members 108′. The second inner spacers 140′b also include the air gaps 142 embedded therein, and the air gaps 142 are spaced apart from the source/drain structures 150.

FIG. 5 illustrates an enlarged cross-sectional view of a semiconductor structure 100c in accordance with some embodiments. The semiconductor structure 100c may be similar to the semiconductor structure 100 described previously, except the size of the dielectric structures are different from that of the semiconductor structure 100 in accordance with some embodiments. Processes and materials for forming the semiconductor structure 100c may be similar to, or the same as, those for forming the semiconductor structure 100 described previously and are not repeated herein. For example, the enlarged cross-sectional view shown in FIG. 5 may be similar to that shown in FIG. 2O-3, and other elements in the semiconductor structure 100c not shown in FIG. 5 may be similar to, or the same as, those shown in FIGS. 2O-1, 2O-2, and 2O-3 described previously in accordance with some embodiments.

More specifically, the semiconductor structure 100c includes dielectric structures 144c, and each of the dielectric structures 144c includes the first inner spacer 134′ and a second inner spacer 140′c in accordance with some embodiments. The formation of the second inner spacer 140′c may be the same as that of the second inner spacer 140′ described above, except after the trimming process for trimming the second inner spacer layer, the outer sidewall of the second inner spacer 140′c is indented from the edges of the channel members 108′, as shown in FIG. 5 in accordance with some embodiments. In some embodiments, the outer sidewall of the second inner spacer 140′c is indented from the edges of the channel members 108′ for a lateral distance D_{IN144c} no greater than 1 nm. The second inner spacers 140′c also include the air gaps 142 embedded therein, and therefore the lateral distance D_{IN144c} should not be too large, or the air gaps 142 may be exposed, and the source/drain structures 150 may extend into the air gaps 142.

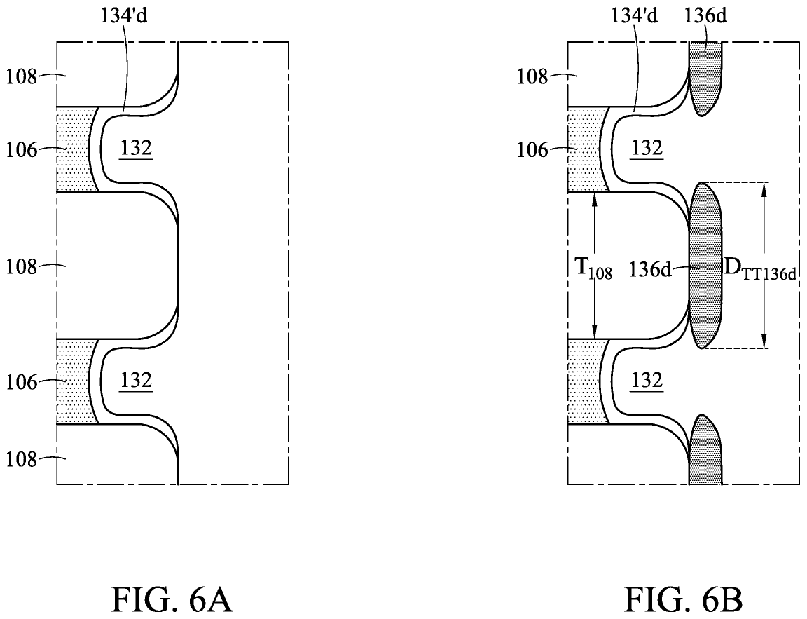

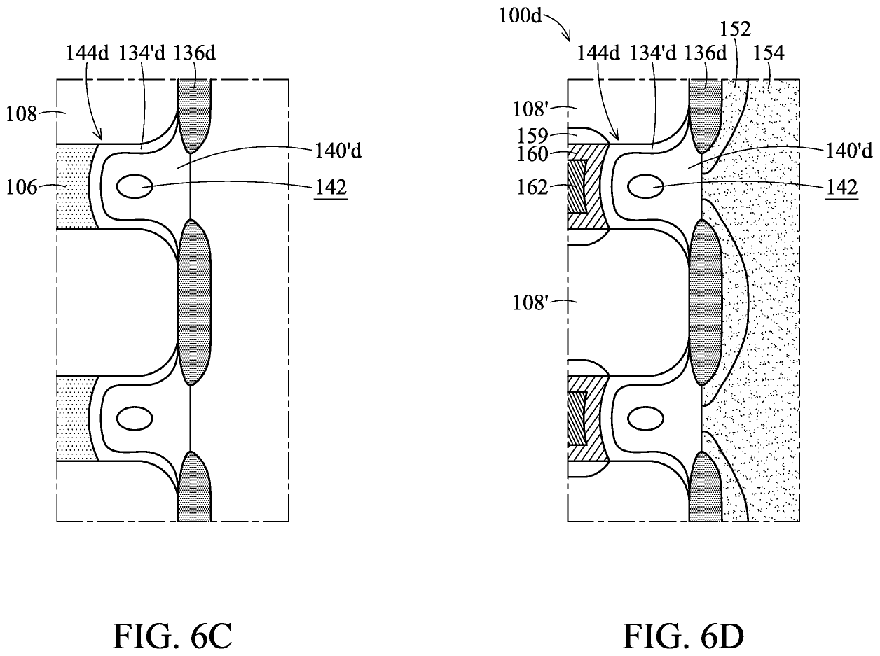

FIGS. 6A to 6D illustrate enlarged cross-sectional views of intermediate stages of manufacturing a semiconductor structure 100d in accordance with some embodiments. The semiconductor structure 100d may be similar to the semiconductor structure 100 described previously, except the dielectric structures are different from that in the semiconductor structure 100 in accordance with some embodiments. Processes and materials for forming the semiconductor structure 100d may be similar to, or the same as, those for forming the semiconductor structure 100 described previously and are not repeated herein. For example, the enlarged cross-sectional view shown in FIG. 6A may be similar to that shown in FIG. 2H-3, the enlarged cross-sectional view shown in FIG. 6B may be similar to that shown in FIG. 2I-3, the enlarged cross-sectional view shown in FIG. 6C may be similar to that shown in FIG. 2K-3, and the enlarged cross-sectional view shown in FIG. 6D may be similar to that shown in FIG. 2O-3. Other elements in the semiconductor structure 100d not shown in FIGS. 6A to 6D may be similar to, or the same as, those shown in FIGS. 2O-1, 2O-2, and 2O-3 described previously in accordance with some embodiments.

More specifically, the processes shown in FIGS. 2A-1 to 2G-1 and 2A-2 to 2G-2 are performed, and the first inner spacer layer (e.g. the first inner spacer layer 134 shown in FIGS. 2G-1, 2G-2, and 2G-3) is trimmed to form first inner spacers 134′d, as shown in FIG. 6A in accordance with some embodiments. In some embodiments, the first inner spacers 134′d completely cover the top and bottom surfaces of the first semiconductor material layers 108 exposed by the notches 132. In some embodiments, the edges of the first inner spacers 134′d are substantially aligned with the edges of the first semiconductor material layers 108.

After the first inner spacers 134′d are formed, epitaxial layers 136d are formed from the exposed edge portions of the first semiconductor material layers 108, as shown in FIG. 6B in accordance with some embodiments. The epitaxial layers 136d has a vertical dimension D_{TT136d} being greater than a thickness T₁₀₈ of the second semiconductor material layer 108.

Afterwards, the processes shown in FIGS. 2J-1 to 2K-1 and 2J-2 to 2K-2 are performed to form dielectric structures 144d, as shown in FIG. 6C in accordance with some embodiments. Each of the dielectric structures 144d includes the first inner spacer 134′d and a second inner spacer 140′d having the air gap 142.

Next, processes shown in FIGS. 2L-1 to 2O-1 and 2L-2 to 2O-2 are performed to form the semiconductor structure 100d, as shown in FIG. 6D in accordance with some embodiments. The processes and materials for forming the first inner spacers 134′d, the epitaxial layers 136d, and the second inner spacers 140′d are similar to, or the same as, those for forming the first inner spacers 134′, the epitaxial layers 136, and the second inner spacers 140′ described previously and are not repeated herein.

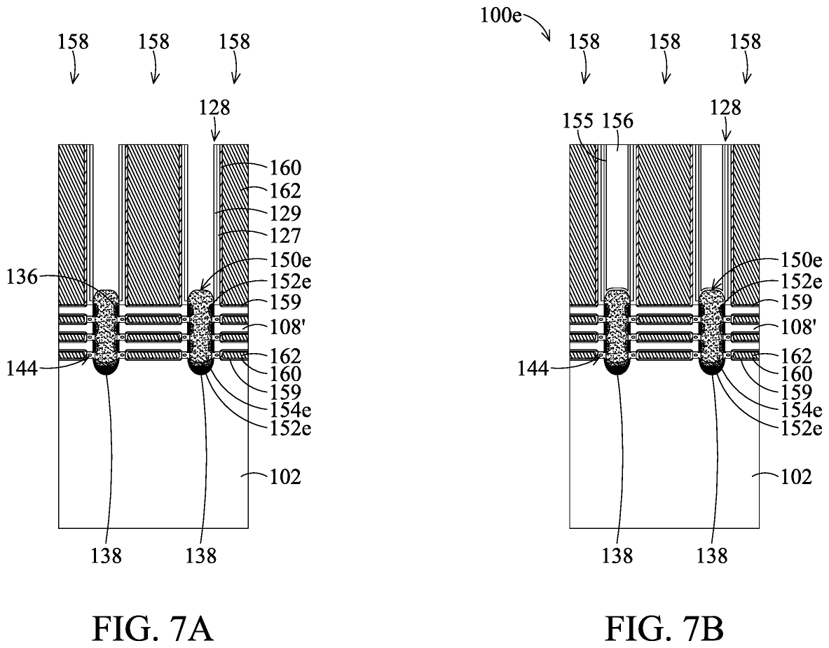

FIGS. 7A and 7B illustrate cross-sectional views of intermediate stages of manufacturing a semiconductor structure 100e in accordance with some embodiments. The semiconductor structure 100e may be similar to the semiconductor structure 100 described previously, except the bottom isolation structures are not formed in accordance with some embodiments. Processes and materials for forming the semiconductor structure 100e may be similar to, or the same as, those for forming the semiconductor structure 100 described previously and are not repeated herein.

More specifically, the processes shown in FIGS. 2A-1 to 2K-1 and 2A-2 to 2K-2 are performed to form the dielectric structures 144, and source/drain structures 150e are formed in the source/drain recesses, as shown in FIG. 7A in accordance with some embodiments. That is, the formation of the bottom isolation structures (e.g. the bottom isolation structures 146 shown in FIG. 2L-2) is omitted and the bottom epitaxial layers 138 are exposed when the source/drain structures 150e are formed.

In some embodiments, each of the source/drain structures 150e includes first portions 152e and a second portion 154e. In some embodiments, the first portions 152e are grown from the exposed portions of the epitaxial layers 136 and the exposed top surface of the bottom epitaxial layers 138, and the second portions 154e are formed over the first portions 152e, and the source/drain recesses are completely filled with the second portions 154e. In some embodiments, the first portions 152e include separated portions grown from each of the exposed sidewalls of epitaxial layers 136 and a bottom portion continuously and laterally extending between two sides of the bottommost dielectric structures 144. In some embodiments, the first portions 152e are in direct contact with the dielectric structures 144. In addition, the topmost portions of the first portions 152e of the source/drain structures 150e are in direct contact with the gate spacers 128, and the bottommost portions of the first portions 152e of the source/drain structures 150e are in direct contact with the bottom epitaxial layers 138 in accordance with some embodiments. In some embodiments, the second portions 154e are formed in the source/drain recesses around the first portions 152e. In some embodiments, the second portions 154e are also in direct contact with the dielectric structures 144 and the gate spacers 128.

After the source/drain structures 150e are formed, the contact etch stop layer (CESL) 155 and the interlayer dielectric (ILD) layer 156 are formed, and the processes shown in FIGS. 2M-1 to 2O-1 and 2M-2 to 2O-2 are performed to form the semiconductor structure 100e, as shown in FIG. 7B in accordance with some embodiments. The processes and materials for forming the source/drain structures 150e are similar to, or the same as, those for forming the source/drain structures 150 described previously and are not repeated herein.

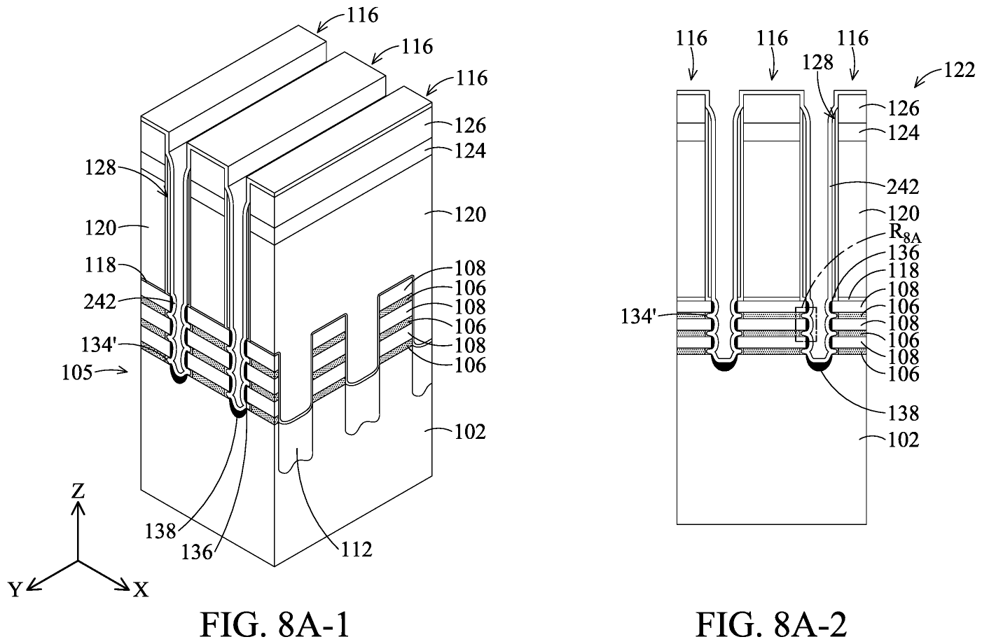

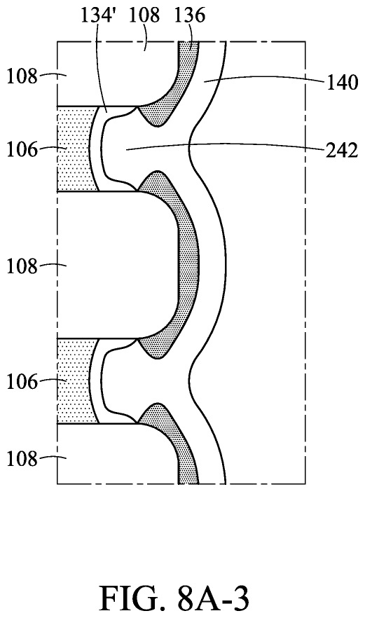

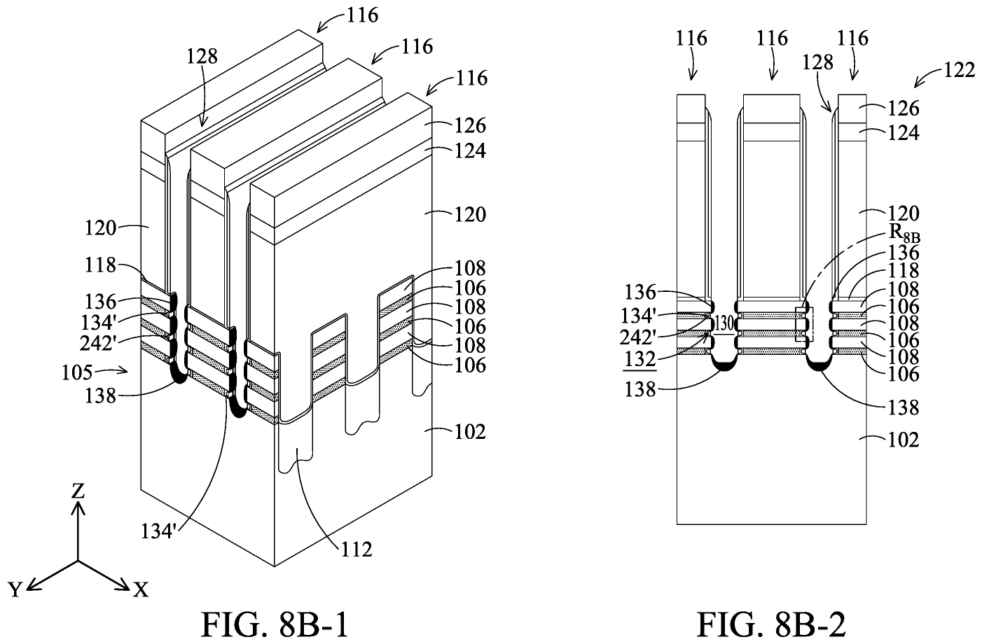

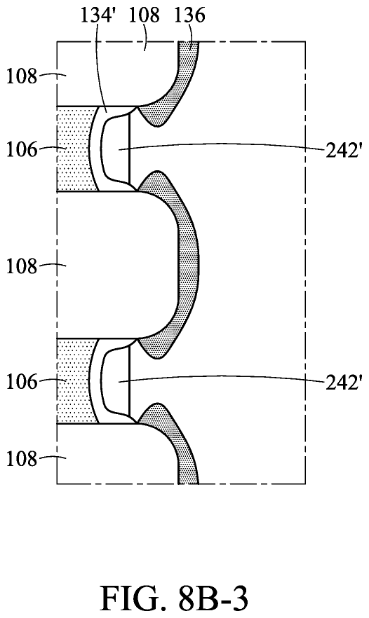

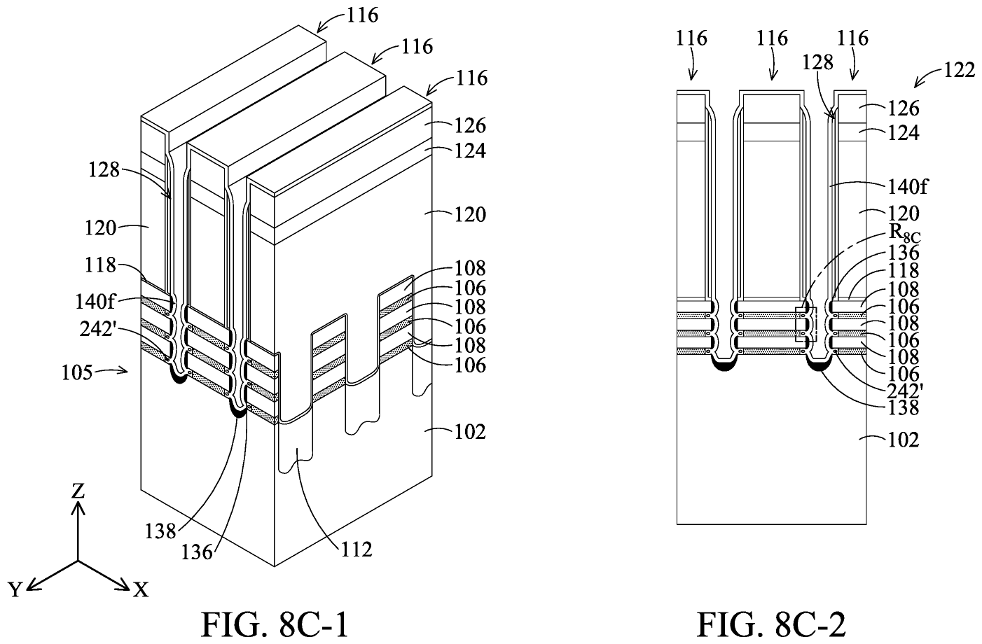

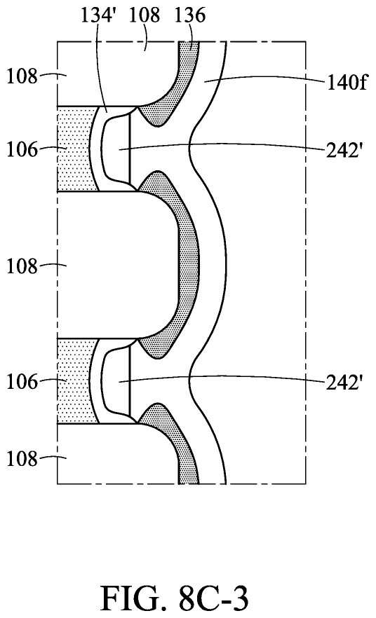

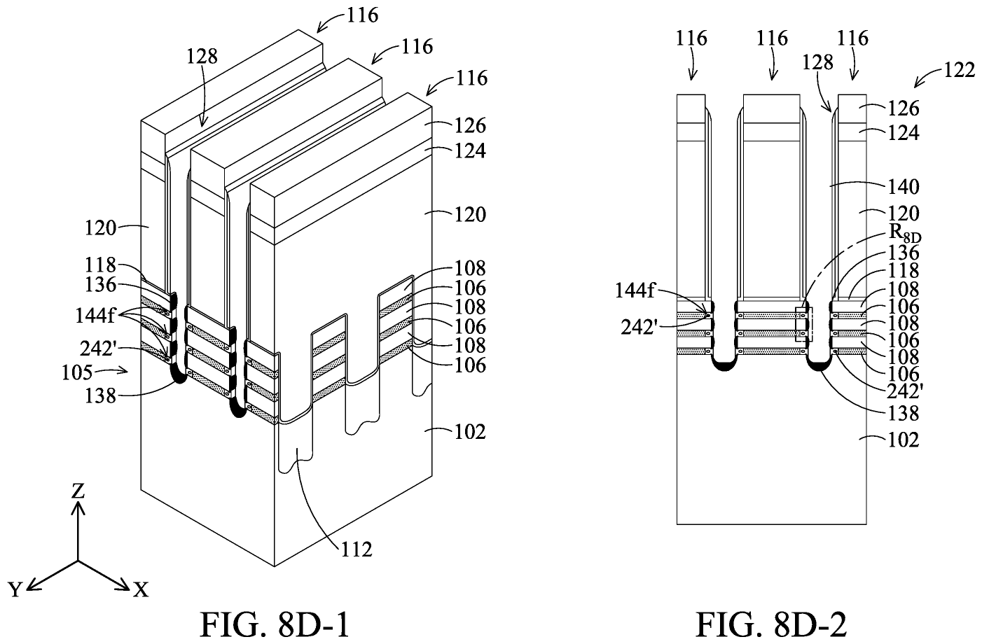

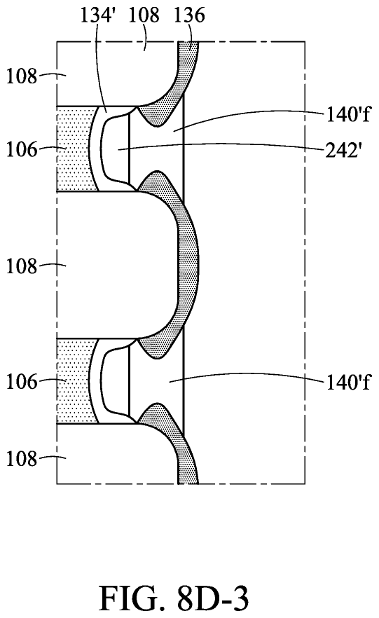

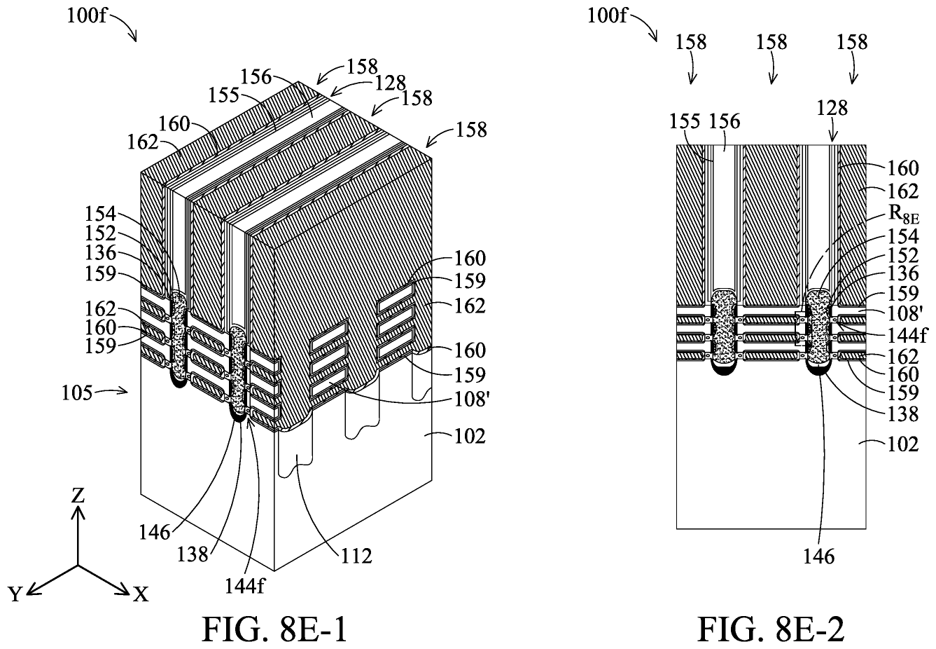

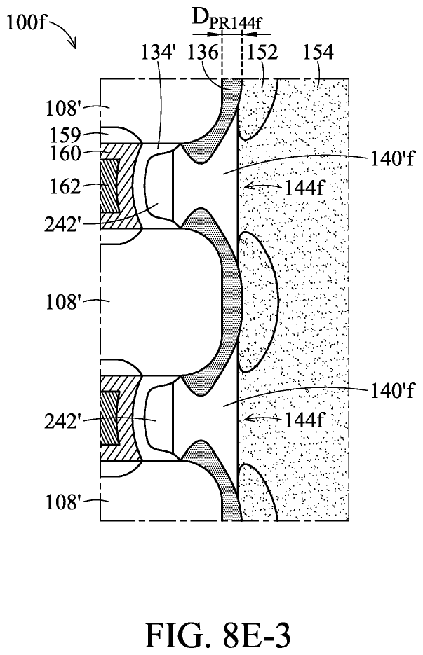

FIGS. 8A-1 to 8E-1 illustrate diagrammatic perspective views of intermediate stages of manufacturing a semiconductor structure 100f in accordance with some embodiments. FIGS. 8A-2 to 8E-2 illustrate cross-sectional views of the intermediate stages of manufacturing the semiconductor structure 100f shown along line A₁-A₁′ in FIG. 8A-1 in accordance with some embodiments. FIGS. 8A-3 to 8E-3 illustrate enlarged cross-sectional views of the intermediate stages of manufacturing the semiconductor structure 100f of regions R_{8A} to R_{8E} shown in FIGS. 8A-2 to 8E-2 in accordance with some embodiments. The semiconductor structure 100f may be similar to the semiconductor structure 100 described previously, except the dielectric structures are different from that in the semiconductor structure 100 accordance with some embodiments. Processes and materials for forming the semiconductor structure 100f may be similar to, or the same as, those for forming the semiconductor structure 100 described previously and are not repeated herein.

More specifically, the processes shown in FIGS. 2A-1 to 2I-1 and 2A-2 to 2I-2 are performed to form the first inner spacers 134′ and the epitaxial layers 136, and a porous material layer 242 is formed afterwards, as shown in FIGS. 8A-1, 8A-2, and 8A-3 in accordance with some embodiments. The porous material layer 242 may also help reduce the k value of the resulting dielectric structures. As shown in FIG. 8A-2, the porous material layer 242 is formed in the notches 132 and in the source/drain recesses 130 and also covering the dummy gate structures 116 and the gate spacers 128 in accordance with some embodiments. In addition, the porous material layer 242 covers the first inner spacers 134′ in the notches, the epitaxial layers 136 over the second semiconductor material layers 108, and the bottom epitaxial layers 138 in the source/drain recesses 130 in accordance with some embodiments.

In some embodiments, the porous material layer 242 is made of a low k dielectric material, such as silicon nitride (SiN), silicon carbon nitride (SiCN), silicon oxynitride (SiON), silicon oxide carbonitride (SiOCN), silicon oxycarbide (SiOC), silicon oxynitride (SiON), or the like. In some embodiments, the porous material layer 242 is made of a SiOCN with 20-45% of Si contents, about 20-65% of O contents, about 5-20% of C contents, and about 1-20% of N contents during the deposition process. The concentration of each element may be designed to form the material with porous structure, so that the k value of the material may be relatively low. For example, C may help to form porous structure in the SiOCN layer, and N may help to control the etching rate of the SiOCN layer during subsequent etching process.

After the porous material layer 242 is formed, a trimming process is performed to form porous material cores 242′, as shown in FIGS. 8B-1, 8B-2, and 8B-3 in accordance with some embodiments. More specifically, an etching process may be performed onto the porous material layer 242 to remove the porous material layer 242 formed over the dummy gate structures 116, the gate spacers 128, and the source/drain recesses 130 in accordance with some embodiments. Accordingly, the porous material cores 242′ are formed next to the first inner spacers 134′ in the notches 132 in accordance with some embodiments. In some embodiments, the trimming process is a dry etching process. In some embodiments, the dry etching process includes using fluorine-containing gas, such as CH₃F or CF₄.

In some embodiments, the porous material cores 242′ cover the sidewalls of the first inner spacers 134′. In some embodiments, the porous material cores 242′ are spaced apart from the epitaxial layers 136, as shown in FIG. 8B-3. In some embodiments, the porous material cores 242′ are completely vertically under (e.g. overlap) the second semiconductor material layers 108. That is, the porous material cores 242′ indented from the edges of the second semiconductor material layers 108. In some embodiments, the porous material core 242′ has a height H_{242′} in a range from about 2 nm to about 6 nm. In some embodiments, the porous material core 242′ has a width W_{242′} in a range from about 2 nm to about 4 nm. The size of the porous material cores 242′ should be great enough to have a lower k value. On the other hand, the porous material cores 242′ should not be too large, or it may be exposed in subsequent etching processes.

After the porous material cores 242′ are formed, a second inner spacer layer 140f is formed over the porous material cores 242′ and in the source/drain recesses 130 and also covering the dummy gate structures 116 and the gate spacers 128, as shown in FIGS. 8C-1, 8C-2, and 8C-3 in accordance with some embodiments. More specifically, the second inner spacer layer 140f covers the porous material cores 242′, the epitaxial layers 136 over the second semiconductor material layers 108, and the bottom epitaxial layers 138 in the source/drain recesses 130 in accordance with some embodiments.

In some embodiments, the second inner spacer layer 140f is made of a low k dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the second inner spacer layer 140f is made of a dielectric material the same as that the first inner spacer layer 134 is made of. In some embodiments, the second inner spacer layer 140f and the first inner spacer layer 134 are made of different dielectric materials.

After the second inner spacer layer 140f is formed, a trimming process is performed to form second inner spacers 140′f, as shown in FIGS. 8D-1, 8D-2, and 8D-3 in accordance with some embodiments. More specifically, an etching process may be performed onto the second inner spacer layer 140f to remove the second inner spacer layer 140f formed over the dummy gate structures 116, the gate spacers 128, and the source/drain recesses 130 in accordance with some embodiments. Accordingly, the second inner spacers 140′f are formed next to the porous material cores 242′ in accordance with some embodiments. In some embodiments, the trimming process is a dry etching process. In some embodiments, the dry etching process includes using fluorine-containing gas, such as CH₃F or CF₄.

In some embodiments, the second inner spacers 140′f cover the sidewalls of the porous material cores 242′. In addition, the second inner spacers 140′ partially cover the first inner spacers 134′ and the epitaxial layers 136, as shown in FIG. 8D-3 in accordance with some embodiments. In some embodiments, the epitaxial layers 136 extend into the second inner spacers 140′f.

The first inner spacers 134′, the porous material cores 242′, and the second inner spacers 140′ may be seen as dielectric structures 144f, which are configured to separate the gate structures 158 and the source/drain structures 150 formed afterwards. As described previously, the porous material cores 242′ are sandwiched between the first inner spacers 134′ and the second inner spacers 140′f, so that the k value of the dielectric structures 144f may be relatively low. In some embodiments, the second inner spacers 140′f of the dielectric structures 144f laterally protrude from the sidewalls of the second semiconductor material layers 108. In some embodiments, the second inner spacers 140′f of the dielectric structures 144f laterally protruding from the sidewalls of the second semiconductor material layers 108 for a distance D_{PR144f} no more than 2 nm.

After the dielectric structures 144f are formed, the processes shown in FIGS. 2L-1 to 2O-1 and 2L-2 to 2O-2 are performed to form the semiconductor structure 100f, as shown in FIGS. 8E-1, 8E-2, and 8E-3 in accordance with some embodiments. As described previously, the semiconductor structure 100f includes dielectric structures 144f formed between the gate structures 158 and the source/drain structures 150 in accordance with some embodiments. In addition, dielectric structures 144f includes a periphery region and a core region, and the periphery region includes the first inner spacer 134′ and the second inner spacer 140′f and the core region include the porous material core 242′ in accordance with some embodiments. Since the porous material cores 242′ are formed in the dielectric structures 144f, the dielectric structures 144f may have relatively low k value, and the capacitance of the resulting semiconductor structure 100f may be reduced. In some embodiments, the ratio of the size of the porous material core 242′ to the size of the dielectric structure 144f is in a range from about 20% to about 60%, and the capacitance/performance of the resulting semiconductor device may be improved for about 3% to about 10%.

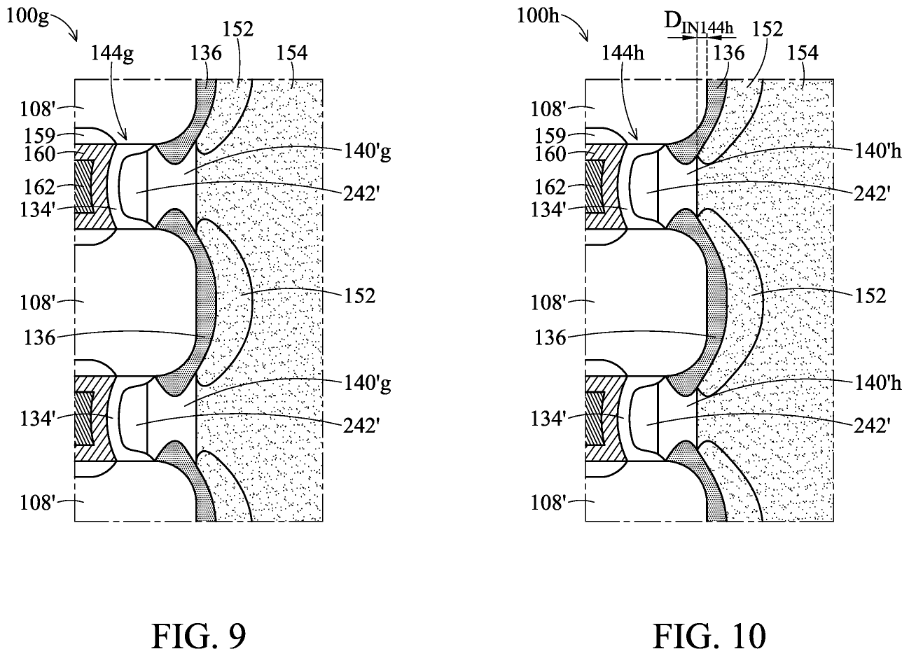

FIG. 9 illustrates an enlarged cross-sectional view of a semiconductor structure 100g in accordance with some embodiments. The semiconductor structure 100g may be similar to the semiconductor structure 100f described previously, except the size of the dielectric structures are different from that in the semiconductor structure 100f in accordance with some embodiments. Processes and materials for forming the semiconductor structure 100g may be similar to, or the same as, those for forming the semiconductor structure 100f described previously and are not repeated herein. For example, the enlarged cross-sectional view shown in FIG. 9 may be similar to that shown in FIG. 8E-3, and other elements in the semiconductor structure 100g not shown in FIG. 9 may be similar to, or the same as, those shown in FIGS. 8E-1, 8E-2, and 8E-3 described previously in accordance with some embodiments.

More specifically, the semiconductor structure 100g includes dielectric structures 144g, and each of the dielectric structures 144g includes the first inner spacer 134′, the porous material core 242′, and a second inner spacer 140′g. The formation of the second inner spacer 140′g may be the same as that of the second inner spacer 140′f described above, except after the trimming process for trimming the second inner spacer layer, the outer sidewall of the second inner spacer 140′g does not laterally extend outside the edges of the channel members 108′, as shown in FIG. 9 in accordance with some embodiments. In some embodiments, the outer edge of the second inner spacer 140′g is substantially aligned with the edges of the channel members 108′.

FIG. 10 illustrates an enlarged cross-sectional view of a semiconductor structure 100h in accordance with some embodiments. The semiconductor structure 100h may be similar to the semiconductor structure 100f described previously, except the size of the dielectric structures are different from the in the semiconductor structure 100f in accordance with some embodiments. Processes and materials for forming the semiconductor structure 100h may be similar to, or the same as, those for forming the semiconductor structure 100f described previously and are not repeated herein. For example, the enlarged cross-sectional view shown in FIG. 10 may be similar to that shown in FIG. 8E-3, and other elements in the semiconductor structure 100h not shown in FIG. 10 may be similar to, or the same as, those shown in FIGS. 8E-1, 8E-2, and 8E-3 described previously in accordance with some embodiments.

More specifically, the semiconductor structure 100h includes dielectric structures 144h, and each of the dielectric structures 144h includes the first inner spacer 134′, the porous material core 242′, and a second inner spacer 140′h in accordance with some embodiments. The formation of the second inner spacer 140′h may be the same as that of the second inner spacer 140′f described above, except after the trimming process for trimming the second inner spacer layer, the outer sidewall of the second inner spacer 140′h is indented from the edges of the channel members 108′, as shown in FIG. 10 in accordance with some embodiments. In some embodiments, the outer edge of the second inner spacer 140′h is indented from the edges of the channel members 108′ for a lateral distance D_{IN144h} no greater than 1 nm.

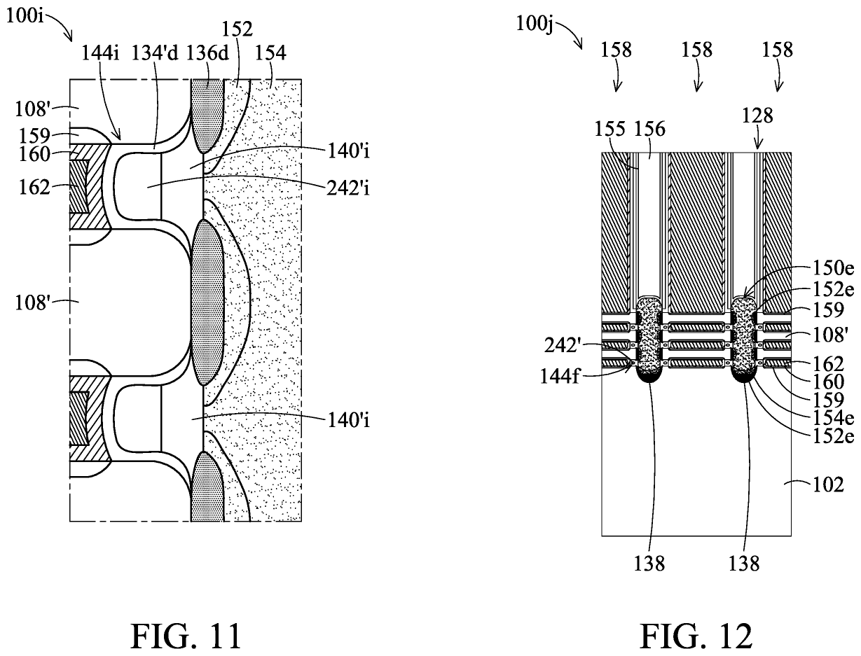

FIG. 11 illustrates an enlarged cross-sectional view of a semiconductor structure 100i in accordance with some embodiments. The semiconductor structure 100i may be similar to the semiconductor structure 100f described previously, except the dielectric structures are different from that in the semiconductor structure 100f in accordance with some embodiments. Processes and materials for forming the semiconductor structure 100i may be similar to, or the same as, those for forming the semiconductor structure 100f described previously and are not repeated herein. For example, the enlarged cross-sectional view shown in FIG. 11 may be similar to that shown in FIG. 8E-3, and other elements in the semiconductor structure 100i not shown in FIG. 11 may be similar to, or the same as, those shown in FIGS. 8E-1, 8E-2, and 8E-3 described previously in accordance with some embodiments.

More specifically, the first inner spacers 134′d (i.e. the same as that shown in FIG. 6A) is formed, and the processes shown in FIGS. 8A-1 to 8E-1, 8A-2 to 8E-2, and 8A-3 to 8E-3 are performed to form the semiconductor structure 100i. The semiconductor structure 100i includes dielectric structures 144i, and each of the dielectric structures 144i includes the first inner spacer 134′d, a porous material core 242′i, and a second inner spacer 140′I in accordance with some embodiments. The processes and materials for forming the porous material cores 242′i and the second inner spacers 140′i are similar to, or the same as, those for forming the porous material cores 242′ and the second inner spacers 140′f described previously and are not repeated herein.

FIG. 12 illustrates a cross-sectional view of a semiconductor structure 100j in accordance with some embodiments. The semiconductor structure 100j may be similar to the semiconductor structure 100f described previously, except the bottom isolation structures are not formed in accordance with some embodiments. Processes and materials for forming the semiconductor structure 100j may be similar to, or the same as, those for forming the semiconductor structure 100f described previously and are not repeated herein. More specifically, the semiconductor structure 100j includes the dielectric structures 144f and the source/drain structures 150e (e.g. the same as that shown in FIG. 7B).

Generally, dielectric structures may be formed between the gate structures and source/drain structures. However, the k value of the dielectric structure may affect the performance (e.g. required AC of the device, effective capacitance, or the like) of the resulting device. Accordingly, in the embodiments described above, the dielectric structures (e.g. the dielectric structures 144, 144b, 144c, 144d, 144f, 144g, 144h, and 144i) are formed with a periphery region and a core region, and the core region of the dielectric structures may have relatively low k value. In some embodiments, the core regions include air gaps (e.g. the air gap 142) or porous material cores (e.g. the porous material cores 242′ and 242′i).

Furthermore, additional epitaxial layers (e.g. the epitaxial layers 136) are formed to narrow the opening of the notches (e.g. the notches 132), so that the air gap tends to be formed in the notches, and the position of porous material core can also be confined. In addition, the thickness of the epitaxial layers may be different due to the different growth rate of the epitaxial material at different orientation, therefore the opening of the notches may be shrunk by growing the epitaxial material, and no complicated manufacturing processes are required.

It should be appreciated that the elements shown in the semiconductor structures 100 and 100a to 100j may be combined and/or exchanged. For example, a semiconductor structure may include the dielectric structure shown in the semiconductor structures 100b to 100j with the source/drain structures shown in the semiconductor structure 100a.

In addition, it should be noted that same elements in FIGS. 1 to 12 may be designated by the same numerals and may include materials that are the same or similar and may be formed by processes that are the same or similar; therefore such redundant details are omitted in the interests of brevity. In addition, although FIGS. 1 to 12 are described in relation to the method, it will be appreciated that the structures disclosed in FIGS. 1 to 12 are not limited to the method but may stand alone as structures independent of the method. Similarly, the methods shown in FIGS. 1 to 12 are not limited to the disclosed structures but may stand alone independent of the structures. Furthermore, the channel members described above may include nanostructures such as nanowires, nanosheets, or other applicable nanostructures in accordance with some embodiments.

Also, while the disclosed methods are illustrated and described below as a series of acts or events, it should be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure may include channel members and a gate structure wrapping around the channel members. In addition, source/drain structures are attached to the channel members at opposite sides of the gate structure, and dielectric structures are sandwiched between the gate structure and the source/drain structures. Furthermore, the dielectric structures include core regions with air gaps or a porous material, so that the k value of the dielectric structures may be relatively low, and the semiconductor device may have lower capacitance. Accordingly, the performance of the semiconductor device may be improved.

In some embodiments, a semiconductor structure is provided. The semiconductor structure includes a first channel member suspended over a substrate and a second channel member suspended over the first channel member and spaced apart from the first channel member along a first direction. The semiconductor structure also includes a gate structure longitudinally oriented along a second direction being substantially orthogonal to the first direction and wrapping around the first channel member and the second channel member and a dielectric structure encircled by the first channel member, the second channel member, the gate structure, and the source/drain structure. In addition, the dielectric structure includes a porous material or an air gap. The semiconductor structure also includes a first epitaxial layer attached to the first channel member, and the first epitaxial layer has a first extending portion protruding from a bottom surface of the first channel member along the first direction and extending into the dielectric structure.

In some embodiments, a semiconductor structure is provided. The semiconductor structure includes channel members and dielectric structures vertically sandwiched between the channel members. In addition, each of the dielectric structures includes a periphery region and a core region surrounded by the periphery region, and the core region includes a porous material or an air gap. The semiconductor structure also includes a gate structure wrapping around the channel members and attached to first sidewalls of periphery region of the dielectric structures and a source/drain structure attached to second sidewalls of periphery region of the dielectric structures. In addition, the second sidewalls are opposite to the first sidewalls. The semiconductor structure also includes epitaxial layers sandwiched between the source/drain structure and channel members.

In some embodiments, a method for manufacturing a semiconductor structure is provided. The method for manufacturing the semiconductor structure includes alternately stacking first semiconductor material layers and second semiconductor material layers to form a semiconductor stack over a substrate and patterning the semiconductor stack to form a fin structure. The method for manufacturing the semiconductor structure also includes forming a dummy gate structure across the fin structure and forming source/drain trenches in the fin structure at opposite sides of the dummy gate structure. The method for manufacturing the semiconductor structure also includes recessing the first semiconductor material layers from the source/drain trenches to form notches between the second semiconductor material layers and forming first inner spacers covering inner sidewalls of the notches. The method for manufacturing the semiconductor structure also includes forming epitaxial layers laterally grown from the second semiconductor material layers and forming second inner spacers in the notches after the epitaxial layers are formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first channel member suspended over a substrate;
a second channel member suspended over the first channel member and spaced apart from the first channel member along a first direction;
a gate structure longitudinally oriented along a second direction being substantially orthogonal to the first direction and wrapping around the first channel member and the second channel member;
a dielectric structure encircled by the first channel member, the second channel member, the gate structure, and the source/drain structure, wherein the dielectric structure comprises a porous material or an air gap; and
a first epitaxial layer attached to the first channel member, wherein the first epitaxial layer has a first extending portion protruding from a bottom surface of the first channel member along the first direction and extending into the dielectric structure.

2. The semiconductor structure as claimed in claim 1, wherein the dielectric structure protruding from a first edge of the first channel member and a second edge of the second channel member along a third direction is substantially orthogonal to the first direction and the second direction.

3. The semiconductor structure as claimed in claim 1, further comprising:
a second epitaxial layer attached to the first channel member, wherein the second epitaxial layer has a second extending portion protruding from a top surface of the second channel member along the first direction,
wherein the first extending portion of the first epitaxial layer is spaced apart from the second extending portion of the second epitaxial layer.

4. The semiconductor structure as claimed in claim 3, wherein the dielectric structure has a first thickness between the first extending portion of the first epitaxial layer and the second extending portion of the second epitaxial layer along the first direction and a second thickness between the bottom surface of the first channel member and the top surface of the second channel member along the first direction, and the first thickness is smaller than the second thickness.

5. The semiconductor structure as claimed in claim 1, further comprising:
a source/drain structure formed adjacent to the gate structure, wherein the first epitaxial layer is sandwiched between the first channel member and the source/drain structure, and the dielectric structure is sandwiched between the gate structure and the source/drain structure.

6. The semiconductor structure as claimed in claim 5, wherein the dielectric structure further comprises:
a first inner spacer in direct contact with the gate structure; and
a second inner spacer in direct contact with the source/drain structure, wherein the air gap is embedded in the second inner spacer.

7. The semiconductor structure as claimed in claim 5, wherein the dielectric structure further comprises:
a first inner spacer in direct contact with the gate structure;
a second inner spacer in direct contact with the source/drain structure; and
a porous material core sandwiched between the first inner spacer and the second inner spacer, wherein the porous material core is made of the porous material.

8. The semiconductor structure as claimed in claim 1, wherein the first epitaxial layer has a first dimension along the first direction, a second dimension along a third direction being substantially orthogonal to the first direction and the second direction, and a third dimension along a fourth direction different from the first direction, the second direction, and the third direction in a cross-sectional view, and the third dimension is smaller than both the first dimension and the second dimension.

9. The semiconductor structure as claimed in claim 8, the first dimension is in a range from about 1 nm to about 3 nm.

10. A semiconductor structure, comprising:
channel members;
dielectric structures vertically sandwiched between the channel members, wherein each of the dielectric structures comprises:
a periphery region; and
a core region surrounded by the periphery region, wherein the core region comprises a porous material or an air gap;
a gate structure wrapping around the channel members and attached to first sidewalls of periphery region of the dielectric structures;
a source/drain structure attached to second sidewalls of periphery region of the dielectric structures, wherein the second sidewalls are opposite to the first sidewalls; and
epitaxial layers sandwiched between the source/drain structure and channel members.

11. The semiconductor structure as claimed in claim 10, wherein the core regions of the dielectric structures are separated from the epitaxial layers by the periphery regions of the dielectric structures.

12. The semiconductor structure as claimed in claim 10, wherein a vertical distance between the epitaxial layers is smaller than a vertical distance between the channel members.

13. The semiconductor structure as claimed in claim 10, further comprising:
a bottom isolation structure formed under the source/drain structure, wherein the bottom isolation structure is in direct contact with a bottommost one of the dielectric structures.

14. The semiconductor structure as claimed in claim 10, wherein the epitaxial layers are Si layers.

15. The semiconductor structure as claimed in claim 10, wherein the porous material comprises Si, O, C, and N.

16. A method for manufacturing a semiconductor structure, comprising:
alternately stacking first semiconductor material layers and second semiconductor material layers to form a semiconductor stack over a substrate;
patterning the semiconductor stack to form a fin structure;
forming a dummy gate structure across the fin structure;
forming source/drain trenches in the fin structure at opposite sides of the dummy gate structure;
recessing the first semiconductor material layers from the source/drain trenches to form notches between the second semiconductor material layers;
forming first inner spacers covering inner sidewalls of the notches;
forming epitaxial layers laterally grown from the second semiconductor material layers; and
forming second inner spacers in the notches after the epitaxial layers are formed.

17. The method for manufacturing the semiconductor structure as claimed in claim 16, further comprising:
forming porous material cores in the notches after forming the epitaxial layers and before forming the second inner spacers.

18. The method for manufacturing the semiconductor structure as claimed in claim 16, wherein an air gap is embedded in the second inner spacers.

19. The method for manufacturing the semiconductor structure as claimed in claim 16, further comprising:
forming a first inner spacer layer covering the notches, the source/drain trenches, and the dummy gate structure;
partially removing the first inner spacer layer to form the first inner spacers in the notches;
forming a second inner spacer layer in the notches and covering the epitaxial layers, the source/drain trenches, and the dummy gate structure; and
partially removing the second inner spacer layer to form the second inner spacers in the notches.

20. The method for manufacturing the semiconductor structure as claimed in claim 16, further comprising:
removing the dummy gate structure and the first semiconductor material layers to form a gate trench, wherein the first inner spacers are exposed by the gate trench; and
forming a gate structure in the gate trench.
